(19) United States
(12) Patent Application Publication
(10) Pub. No.: US 2025/0081614 A1
(43) Pub. Date: Mar. 6, 2025

(54) DISPLAY APPARATUS AND METHOD OF MANUFACTURING DISPLAY APPARATUS

(71) Applicant: Samsung Display Co., LTD., Yongin-si (KR)

(72) Inventors: Kangyoung LEE, Yongin-si (KR); Hyungil JEON, Yongin-si (KR); Jinwoo CHOI, Yongin-si (KR); Changil TAE, Yongin-si (KR)

(21) Appl. No.: 18/795,974

(22) Filed: Aug. 6, 2024

(30) Foreign Application Priority Data
Sep. 1, 2023 (KR) 10-2023-0116271

(51) Int. Cl. H01L 27/12; H01L 25/16

(52) U.S. Cl. CPC H10D 86/60; H01L 25/167; H10D 86/0231; H10D 86/451

(57) ABSTRACT

A display apparatus includes: a substrate; a pixel driving circuit portion disposed on the substrate; an organic insulating layer disposed on the pixel driving circuit portion and defining a first opening therein; a first conductive organic film accommodated in the first opening to be electrically connected to the pixel driving circuit portion; and an inorganic light-emitting diode disposed on the organic insulating layer and including a first electrode, where at least a portion of the first electrode is accommodated in the first conductive organic film.

This application claims priority to Korean Patent Application No. 10-2023-0116271, filed on Sep. 1, 2023, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the same, and more particularly, to a stretchable display apparatus and a method of manufacturing the same.

### 2. Description of the Related Art

Along with the development of display apparatuses that visually display various electrical signals, various display apparatuses having excellent characteristics such as thinness, light weight, low power consumption, and the like have been introduced. As an example, flexible display apparatuses that are foldable or rollable in a roll shape have been developed. Research and development on stretchable display apparatuses that may change into various shapes have been actively carried out.

### SUMMARY

One or more embodiments include a display apparatus, for example, a stretchable display apparatus.

Additional aspects will be set forth in part in the description which follows and, in part, will be apparent from the description, or may be learned by practice of the presented embodiments of the disclosure.

According to one or more embodiments, a display apparatus includes: a substrate; a pixel driving circuit portion disposed on the substrate; an organic insulating layer disposed on the pixel driving circuit portion and defining a first opening therein; a first conductive organic film accommodated in the first opening to be electrically connected to the pixel driving circuit portion; and an inorganic light-emitting diode disposed on the organic insulating layer and including a first electrode, where at least a portion of the first electrode is accommodated in the first conductive organic film.

An upper surface of the first conductive organic film may be recessed from a top surface of the organic insulating layer.

A thickness of the first electrode may be greater than a height difference between the upper surface of the first conductive organic film and the top surface of the organic insulating layer.

The first conductive organic film may include a carbon black material.

The display apparatus may further include a first connection electrode disposed between the pixel driving circuit portion and the first conductive organic film and electrically connecting the pixel driving circuit portion to the first conductive organic film.

The first connection electrode may include at least one of indium tin oxide (“ITO”), indium zinc oxide (“IZO”), and molybdenum (Mo).

The display apparatus may further include a second conductive organic film apart from the first conductive organic film, the organic insulating layer may further define a second opening which is apart from the first opening and accommodates the second conductive organic film, and the inorganic light-emitting diode may further include a second electrode which is apart from the first electrode and has at least a portion accommodated in the second conductive organic film.

An upper surface of the second conductive organic film may be recessed from the top surface of the organic insulating layer.

A thickness of the second electrode may be greater than a height difference between the upper surface of the second conductive organic film and the top surface of the organic insulating layer.

The second conductive organic film may include a carbon black material.

The display apparatus may further include a second connection electrode disposed between the pixel driving circuit portion and the second conductive organic film and connected to the second conductive organic film.

The second connection electrode may include at least one of indium tin oxide (ITO), indium zinc oxide (IZO), and molybdenum (Mo).

The display apparatus may further include an opposite electrode disposed on the inorganic light-emitting diode, where the inorganic light-emitting diode may further include a second electrode which is apart from the first electrode and is electrically connected to the opposite electrode.

The display apparatus may further include a conductive organic film layer disposed on the organic insulating layer to cover the organic insulating layer in a non-display area.

According to one or more embodiments, a method of manufacturing a display apparatus includes: disposing a pixel driving circuit portion on a substrate; disposing an organic insulating layer on the pixel driving circuit portion; etching the organic insulating layer to form a first opening; disposing a first conductive organic film in the first opening to be electrically connected to the pixel driving circuit portion; and disposing an inorganic light-emitting diode on the organic insulating layer, where the disposing of the inorganic light-emitting diode includes accommodating at least a portion of a first electrode of the inorganic light-emitting diode in the first conductive organic film.

The etching of the organic insulating layer to form the first opening may include dry-etching the organic insulating layer using an etching gas.

The disposing of the first conductive organic film may include disposing a conductive organic film material on the organic insulating layer, soft-baking the conductive organic film material, and developing the conductive organic film material.

The accommodating of at least a portion of the first electrode in the first conductive organic film may include: pressing the first electrode to the first conductive organic film, and heating the first conductive organic film.

The heating of the first conductive organic film may include heating the first conductive organic film to about 120 degrees in Celsius (C) to about 140° C.

The first conductive organic film may include a carbon black material.

The method may further include: etching the organic insulating layer to form a second opening apart from the first opening, and disposing a second conductive organic film in the second opening, where the disposing of the inorganic light-emitting diode may further include accommodating at least a portion of a second electrode of the inorganic light-emitting diode in the second conductive organic film, and the second electrode may be apart from the first electrode.

The etching of the organic insulating layer to form the first opening, and the etching of the organic insulating layer to form the second opening may be performed simultaneously.

The disposing of the first conductive organic film in the first opening, and the disposing of the second conductive organic film in the second opening may be performed simultaneously.

The accommodating of the at least a portion of the first electrode in the first conductive organic film, and the accommodating of the at least a portion of the second electrode in the second conductive organic film may be performed simultaneously.

The method may further include disposing an opposite electrode on the inorganic light-emitting diode, and the disposing of the inorganic light-emitting diode may further include electrically connecting a second electrode of the inorganic light-emitting diode to the opposite electrode, and the second electrode may be apart from the first electrode.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a stretchable display apparatus according to an embodiment;

FIGS. 2A and 2B are perspective views of a state in which the stretchable display apparatus of FIG. 1 is stretched in a first direction;

FIG. 2C is a perspective view showing a state in which the stretchable display apparatus of FIG. 1 is stretched in a second direction;

FIG. 2D is a perspective view showing a state in which the stretchable display apparatus of FIG. 1 is stretched in the first direction and the second direction;

FIG. 2E is a perspective view showing a state in which the stretchable display apparatus of FIG. 1 is stretched in a third direction;

FIG. 3 is a schematic plan view of a stretchable display apparatus according to an embodiment;

FIG. 4A is an enlarged plan view of a portion of a stretchable display apparatus, and a region IV of FIG. 3 according to an embodiment;

FIG. 4B is an enlarged plan view of a portion of a stretchable display apparatus, and a region IV of FIG. 3 according to an embodiment;

FIG. 4C is an enlarged plan view of a portion of a stretchable display apparatus, and a region IV of FIG. 3 according to an embodiment;

FIG. 5 is a schematic cross-sectional view of a first island portion and a first bridge portion arranged in a display area of a stretchable display apparatus according to an embodiment;

FIGS. 6A to 6C are equivalent circuit diagrams of a sub-pixel of a stretchable display apparatus according to an embodiment, respectively;

FIG. 7 is a schematic cross-sectional view of a portion of a display apparatus according to an embodiment;

FIG. 8 is an enlarged view of a region A of FIG. 7 according to an embodiment;

FIG. 9 is an enlarged view of a region B of FIG. 7 according to an embodiment;

FIG. 10 is a schematic cross-sectional view of a portion of a display apparatus according to another embodiment;

FIGS. 11A to 11H are schematic cross-sectional views of a method of manufacturing a display apparatus according to an embodiment;

FIG. 12 is a schematic cross-sectional view of a portion of a display apparatus according to still another embodiment;

FIGS. 13A to 13C are schematic cross-sectional views of a method of manufacturing a display apparatus according to another embodiment; and

FIGS. 14A to 14G are schematic perspective views of embodiments of an electronic apparatus including a stretchable display apparatus according to an embodiment, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value. Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

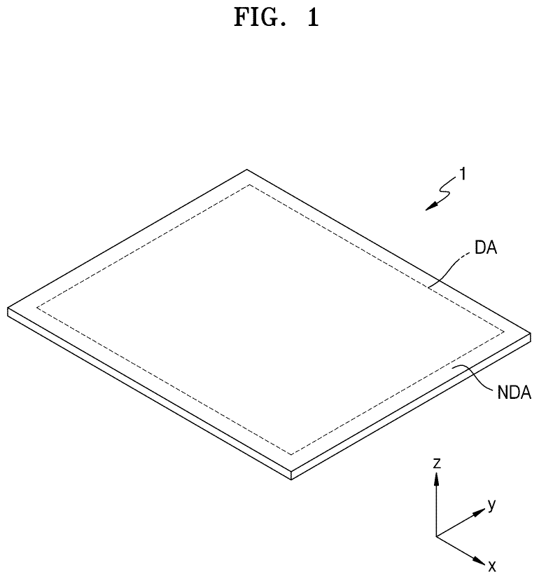

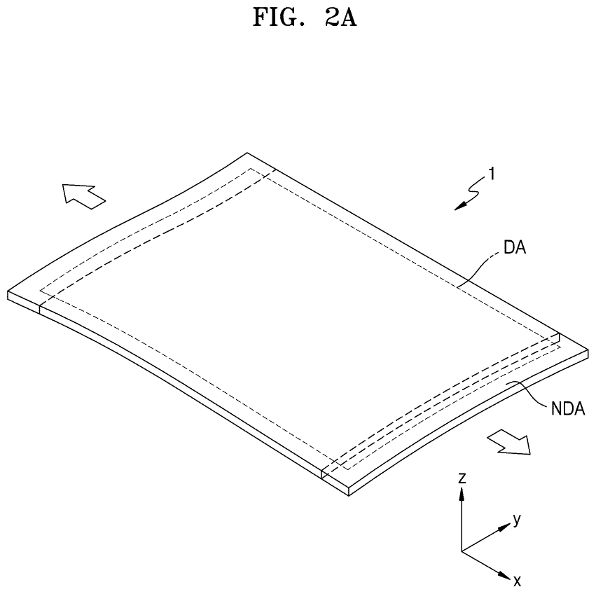

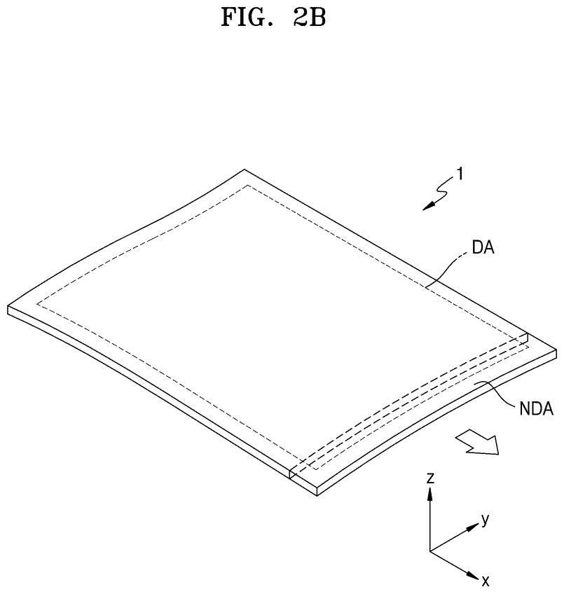

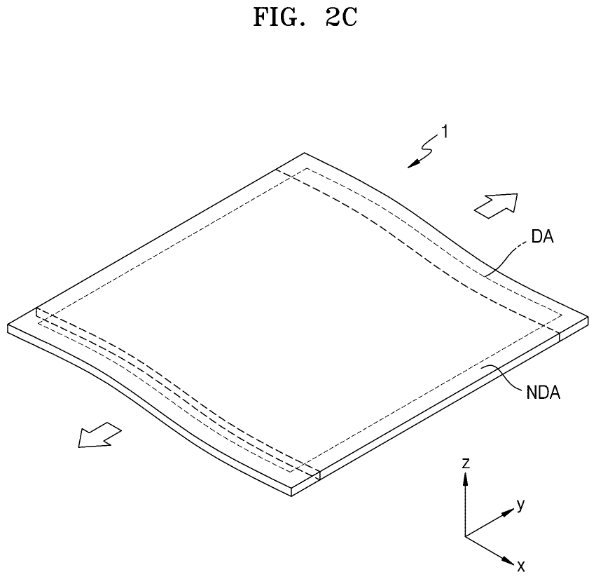

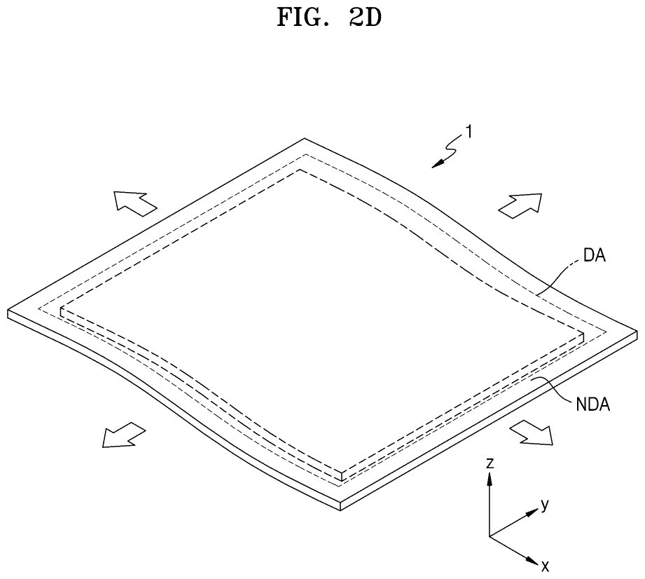

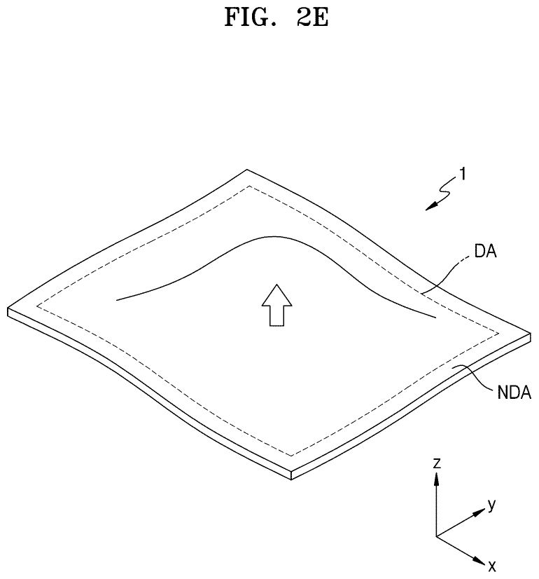

FIG. 1 is a schematic perspective view of a display apparatus 1 according to an embodiment. FIGS. 2A and 2B are perspective views of a state in which the display apparatus 1 of FIG. 1 is stretched in a first direction. FIG. 2C is a perspective view showing a state in which the display apparatus 1 of FIG. 1 is stretched in a second direction. FIG. 2D is a perspective view showing a state in which the display apparatus 1 of FIG. 1 is stretched in the first direction and the second direction. FIG. 2E is a perspective view showing a state in which the display apparatus 1 of FIG. 1 is stretched in a third direction (e.g., z direction or −z direction).

Referring to FIG. 1, the display apparatus 1 may include a display area DA and a non-display area NDA. The display area DA may include a plurality of pixels. The display apparatus 1 may be configured to display preset images by using light emitted from the plurality of pixels. The non-display area NDA may be arranged outside the display area DA. The non-display area NDA may surround the entirety of the display area DA.

The display apparatus 1 may be stretched or shrunk in various directions. The display apparatus 1 may be stretched in a first direction (e.g., an x direction and/or a −x direction) due to external force exerted by an external object or a user. In an embodiment, as shown in FIGS. 2A and 2B, the display area DA and/or the non-display area NDA of the display apparatus 1 may be stretched in the first direction (e.g., the x direction and/or the −x direction). As an example, as shown in FIG. 2A, the display area DA and/or the non-display area NDA may be stretched in the x direction and the −x direction, or be stretched in the x direction with one side of the display apparatus 1 fixed as shown in FIG. 2B.

The display apparatus 1 may be stretched in a second direction (e.g., a y direction and/or a −y direction) due to external force exerted by an external object or a user. In an embodiment, as shown in FIG. 2C, the display area DA and/or the non-display area NDA of the display apparatus 1 may be stretched in the y direction and the −y direction. In another embodiment, the display area DA and/or the non-display area NDA may be stretched in the y direction or the −y direction with one side of the display apparatus 1 fixed.

The display apparatus 1 may be stretched in, for example, the first direction (e.g., the x direction and/or the −x direction) and the second direction (e.g., the y direction and/or the −y direction) due to external force exerted by an external object or a portion of a human body. As shown in FIG. 2D, the display area DA and/or the non-display area NDA of the display apparatus 1 may be stretched in a ±x direction and a ±y direction.

The display apparatus 1 may be stretched in a third direction (e.g., z direction or −z direction) due to external force exerted by an external object or a human body. In an embodiment, it is shown in FIG. 2E that a portion of the display apparatus 1, for example, a partial region of the display area DA protrudes in the z direction. In another embodiment, a portion of the display apparatus 1, for example, a partial region of the display area DA may protrude in a −z direction (or may be recessed in the z direction).

Although it is shown in FIGS. 2A to 2E that the display apparatus 1 is stretched in the first direction, the second direction, and/or the third direction, the embodiment is not limited thereto. In another embodiment, the display apparatus 1 may be transformed into various shapes such as being bent or twisted along two or more axes.

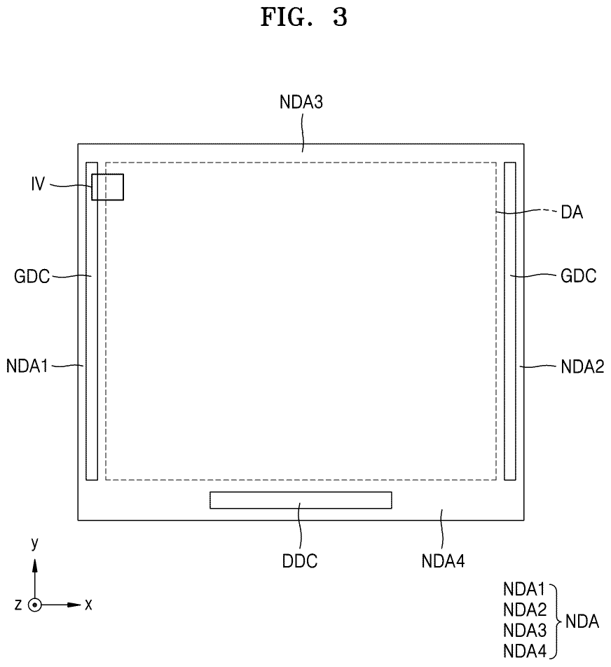

FIG. 3 is a schematic plan view of the display apparatus 1 according to an embodiment. As used herein, the “plan view” is a view in a thickness direction (i.e., z-axis direction) of the substrate 100.

A plurality of pixels may be arranged in the display area DA of the display apparatus 1. Each pixel may include sub-pixels configured to emit light of different colors. A light-emitting element corresponding to each sub-pixel may be arranged in the display area DA. A circuit may be arranged in the non-display area NDA around the display area DA, where the circuit is configured to provide electrical signals to light-emitting elements and transistors electrically connected to the light-emitting elements arranged in the display area DA. Gate driving circuits GDC may be arranged in a first non-display area NDA1 and a second non-display area NDA2, which are arranged on two opposite sides with the display area DA therebetween, respectively. The gate driving circuits GDC may include drivers configured to provide electrical signals to a gate electrode of each of the transistors electrically connected to the light-emitting elements. Although it is shown in FIG. 3 that the gate driving circuits GDC are arranged in the first non-display area NDA1 and the second non-display area NDA2, respectively, the embodiment is not limited thereto. In another embodiment, the gate driving circuit GDC may be arranged in one of the first non-display area NDA1 and the second non-display area NDA2.

A data driving circuit DDC may be arranged in a third non-display area NDA3 and/or a fourth non-display area NDA4 each connecting the first non-display area NDA1 to the second non-display area NDA2. In an embodiment, it is shown in FIG. 3 that the data driving circuit DDC is arranged in the fourth non-display area NDA4. In another embodiment, data driving circuits DDC may be arranged in the third non-display area NDA3 and the fourth non-display area NDA4, respectively.

Although it is shown in FIG. 3 that the data driving circuit DDC is arranged in the fourth non-display area NDA4 of the display apparatus 1, the embodiment is not limited thereto. In another embodiment, the display apparatus 1 may further include a flexible circuit board (not shown) electrically connected through a terminal portion (not shown) arranged in the fourth non-display area NDA4, and the data driving circuit DDC may be arranged on the flexible circuit board.

In an embodiment, an elongation rate of the non-display area NDA may be equal to or less than an elongation rate of the display area DA. In an embodiment, the elongation rate of the non-display area NDA may be different for each region thereof. As an example, although the first non-display area NDA1, the second non-display area NDA2, and the third non-display area NDA3 may have a substantially same elongation rate, an elongation rate of the fourth non-display area NDA4 may be less than the elongation rate of each of the first non-display area NDA1, the second non-display area NDA2, and the third non-display area NDA3.

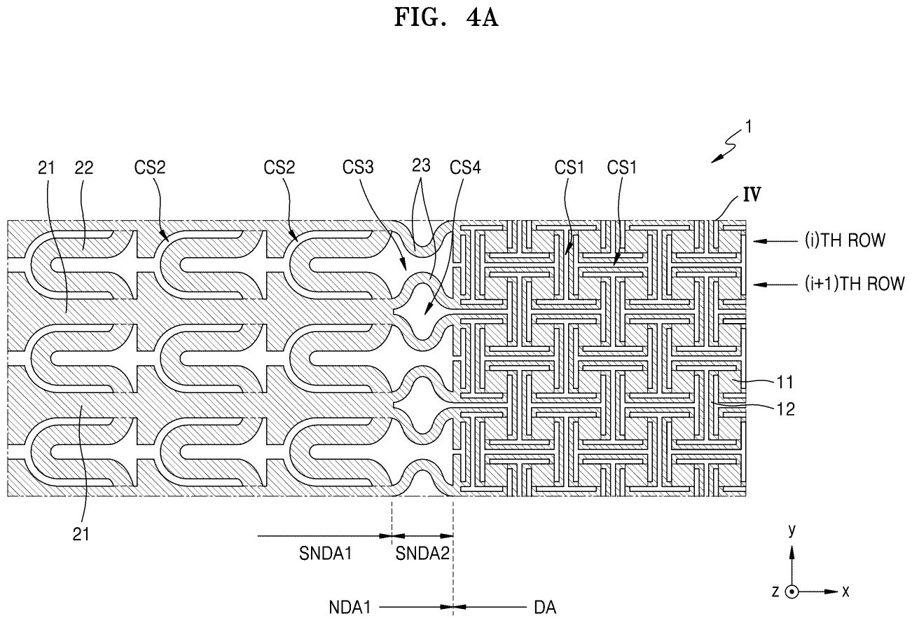

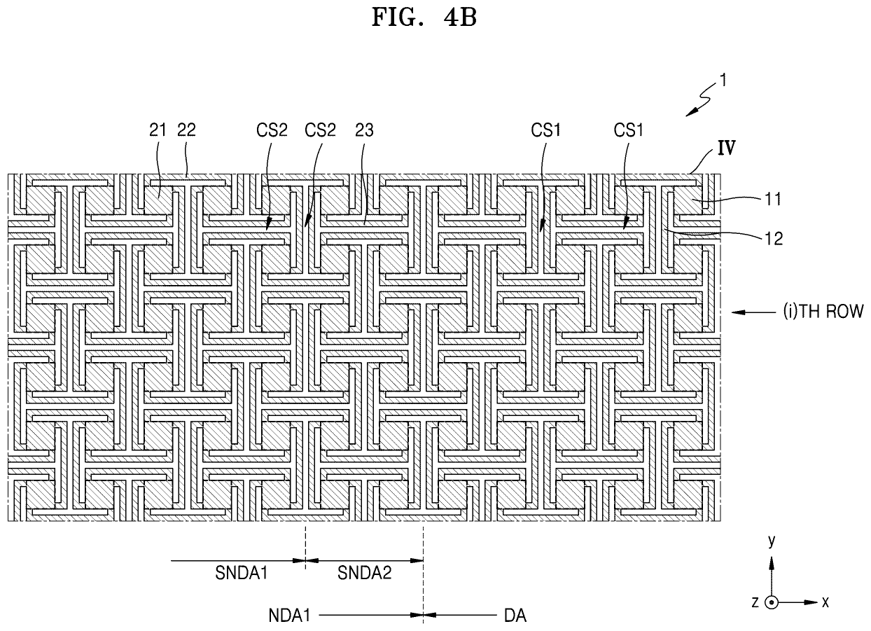

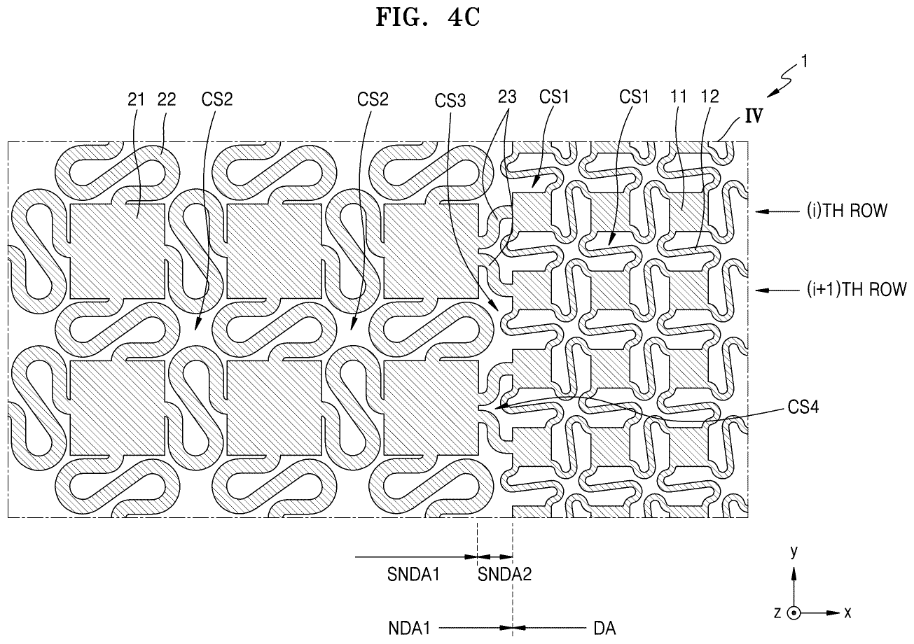

FIG. 4A is an enlarged plan view of a portion of the display apparatus 1, and a region IV of FIG. 3 according to an embodiment.

Referring to FIG. 4A, the display apparatus 1 may include first island portions 11 and first bridge portions 12, where the first island portions 11 are apart from each other in the first direction (e.g., the x direction or the −x direction) and the second direction (e.g., the y direction or the −y direction), and the first bridge portions 12 connect adjacent first island portions 11.

Each first island portion 11 may be connected to a plurality of first bridge portions 12. As an example, each first island portion 11 may be connected to four first bridge portions 12. Two first bridge portions 12 may be arranged on two opposite sides of the first island portion 11 in the first direction (e.g., the x direction or the −x direction), respectively, and the remaining two first bridge portions 12 may be arranged on two opposite sides of the first island portion 11 in the second direction (e.g., the y direction or the −y direction), respectively. In an embodiment, four first bridge portions 12 may be connected to four lateral sides of the first island portion 11, respectively. Each of the four first bridge portions 12 may be adjacent to the respective corners of the first island portion 11.

The first bridge portions 12 may be apart from each other by a first opening CS1 arranged between the first bridge portions 12. In an embodiment, the first openings CS1 having an approximate H shape in the first direction (e.g., the x direction or the −x direction) and the second direction (e.g., the y direction or the −y direction), and the first openings CS1 having an approximate I shape which is rotated by 90 from the H shape may be repeatedly and alternately arranged. Two opposite ends of each first bridge portion 12 may be connected to each of adjacent first island portions 11, and one lateral side of each first bridge portion 12 may be apart from one lateral side of an adjacent first island portion 11 and/or one lateral side of another first island portion 11 by the first opening CS1.

In the non-display area, for example, the first non-display area NDA1 shown in FIG. 4A, the display apparatus 1 may include second island portions 21 apart from each other and second bridge portions 22 connecting adjacent second island portions 21.

Each second island portion 21 may extend in the first direction (e.g., the x direction or the −x direction). The second island portions 21 may be apart from each other in the second direction (e.g., the y direction or the −y direction) crossing the first direction (e.g., the x direction or the −x direction). Each second island portion 21 may include drivers of the gate driving circuit GDC (see FIG. 2) described with reference to FIG. 3.

The second bridge portion 22 may have a serpentine shape. The length of the second bridge portion 22 may be greater than a shortest distance between adjacent second island portions 21 in the second direction (e.g., the y direction or the −y direction). In an embodiment, the second bridge portion 22 may have an approximate omega Ω shape convex in the first direction (e.g., the x direction or the −x direction). The second bridge portions 22 may be arranged between adjacent second island portions 21 and be apart from each other.

The second bridge portions 22 between adjacent second island portions 21 may be apart from each other by a second opening CS2. Between adjacent second island portions 21, the second openings CS2 and the second bridge portions 22 may be alternately arranged in the first direction (e.g., the x direction or the −x direction). The second openings CS2 may have the same shape. Two opposite ends of each second bridge portion 22 may be connected to each of adjacent second island portions 21, and one lateral side of each second bridge portion 22 may be apart from one lateral side of an adjacent second island portion 21 and/or one lateral side of another second island portion 22 by the second opening CS2.

One second island portion 21 arranged in the first non-display area NDA1 may correspond to the first island portions 11 in a plurality of rows arranged in the display area DA. As an example, one second island portion 21 arranged in the first non-display area NDA1 may correspond to the first island portions 11 in an (i)th row and the first island portions 11 in an (i+1)th row in the display area DA (here, i is a positive number greater than 0). Although it is shown in FIG. 4A that one second island portion 21 corresponds to two rows of the first island portions 11, the embodiment is not limited thereto. In another embodiment, one second island portion 21 arranged in the first non-display area NDA1 may correspond to n rows of the first island portions 11 arranged in the display area DA (here, n is a positive number equal to or greater than 3).

The non-display area, for example, the first non-display area NDA1 may include a first sub-non-display area SNDA1 in which the second island portions 21 and the second bridge portions 22 are arranged, and a second sub-non-display area SNDA2 between the first sub-non-display area SNDA1 and the display area DA. Third bridge portions 23 may be arranged in the second sub-non-display area SNDA2, where the third bridge portions 23 connects the display area DA to the first sub-non-display area SNDA1. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may have an approximate omega Ω shape convex in the second direction (e.g., the y direction or the −y direction). The third bridge portions 23 may have a structure that is symmetrical to each other, such that one of the adjacent third bridge portions 23 arranged in the second direction (for example, the y direction or the −y direction) is convex in the y direction and the other is convex in the −y direction. A structure in which third openings CS3 and fourth openings CS4 of different shapes are repeated may be provided between the third bridge portions 23. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

It is shown in FIG. 4A that the second island portion 21 and the second bridge portion 22 in the non-display area NDA, for example, the first non-display area NDA1, have shapes different from the shapes of the first island portion 11 and the first bridge portion 12 in the display area DA, respectively. In another embodiment, the second island portion 21 and the second bridge portion 22 in the non-display area NDA may have the same shapes as the first island portion 11 and the first bridge portion 12 in the display area DA.

FIG. 4B is an enlarged plan view of a portion of the display apparatus 1, and a region IV of FIG. 3 according to an embodiment.

Referring to FIG. 4B, the display apparatus 1 includes the first island portions 11 apart from each other, and the first bridge portions 12 in the display area DA, where the first bridge portions 12 are apart from each other by the first opening CS1 and connect adjacent first island portions 11. The structure of the display area DA in FIG. 4B may be the same as the structure of the display area DA described above with reference to FIG. 4A.

The display apparatus 1 may include the second island portions 21 and the second bridge portions 22 arranged in the non-display area, for example, the first non-display area NDA1. In an embodiment, the second island portions 21 and the second bridge portions 22 may have the substantially same shapes as the first island portions 11 and the first bridge portions 12, respectively.

The second island portions 21 may be apart from each other in the first direction (e.g., the x direction or the −x direction) and the second direction (for example, the y direction or the −y direction) in the non-display area, for example, the first non-display area NDA1. Each of the second bridge portions 22 may connect adjacent second island portions 21. The second bridge portions 22 may be apart from each other by the second opening CS2 arranged between the second bridge portions 22.

The second opening CS2 may have the substantially same shape as the first opening CS1. As an example, the second opening CS2 having an approximate H shape and the second opening CS2 having an approximate I shape may be alternately and repeatedly arranged in the non-display area, for example, the first non-display area NDA1. Two opposite ends of each second bridge portion 22 may be connected to each of adjacent second island portions 21, and one lateral side of each second bridge portion 22 may be apart from one lateral side of an adjacent second island portion 21 and/or one lateral side of another second island portion 22 by the second opening CS2.

Each second island portion 21 may be connected to four second bridge portions 22. Each second island portion 21 may include drivers of the gate driving circuit GDC (see FIG. 2) described with reference to FIG. 3.

The second island portions 21 arranged in one row in the first non-display area NDA1 may correspond to the first island portions 11 in one row arranged in the display area DA. As an example, the second island portions 21 arranged in the (i)th row in the first direction (e.g., the x direction or the −x direction) in the first non-display area NDA1 may correspond to the first island portions 11 arranged in the same row, for example, an (i)th row in the display area DA (here, i is a positive number greater than 0).

The display apparatus 1 may include the third bridge portions 23 arranged in the second sub-non-display area SNDA2, where the third bridge portions 23 connect the display area DA to the first sub-non-display area SNDA1. The non-display area, for example, the first non-display area NDA1 may include the first sub-non-display area SNDA1 in which the second island portions 21 and the second bridge portions 22 are arranged, and the second sub-non-display area SNDA2 including the third bridge portions 23 and arranged between the first sub-non-display area SNDA1 and the display area DA. The third bridge portion 23 may be substantially same as the first bridge portion 12 and the second bridge portion 22. As an example, the width of the third bridge portion 23 may be the same as the width of the first bridge portion 12 and the width of the second bridge portion 22.

FIG. 4C is an enlarged plan view of a portion of the display apparatus 1, and the region IV of FIG. 3 according to an embodiment.

Referring to FIG. 4C, the display apparatus 1 may include first island portions 11 and first bridge portions 12, where the first island portions 11 are apart from each other in the first direction (e.g., the x direction or the −x direction) and the second direction (e.g., the y direction or the −y direction), and the first bridge portions 12 connect adjacent first island portions 11 in the display area DA.

The first bridge portions 12 may be apart from each other by a first opening CS1 arranged between the first bridge portions 12. The first bridge portion 12 may have a curved shape. As an example, as shown in FIG. 4C, the first bridge portion 12 may have an approximate shape of ‘alphabet S’.

Each first island portion 11 may be connected to a plurality of first bridge portions 12. As an example, each first island portion 11 may be connected to four first bridge portions 12. Two first bridge portions 12 may be arranged on two opposite sides of the first island portion 11 in the first direction (e.g., the x direction or the −x direction), respectively, and the remaining two first bridge portions 12 may be arranged on two opposite sides of the first island portion 11 in the second direction (e.g., the y direction or the −y direction), respectively. The four first bridge portions 12 may be connected to four lateral sides of the first island portion 11, respectively. Each of the four first bridge portions 12 may be adjacent to the corners of the first island portion 11, respective.

The display apparatus 1 may include the second island portions 21 and the second bridge portions 22 connecting adjacent second island portions 21, where the second island portions 21 are apart from each other in the first direction (e.g., the x direction or the −x direction) and the second direction (e.g., the y direction or the −y direction) in the first non-display area NDA1 shown in FIG. 4C.

The second bridge portions 22 may be apart from each other by the second opening CS2 arranged between the second bridge portions 22. The second bridge portion 22 may have a serpentine shape. As an example, as shown in FIG. 4C, the second bridge portion 22 may have an approximate shape of ‘alphabet S’. The size and/or width of the second bridge portion 22 may be different from the size and/or width of the first bridge portion 12. As an example, the size and/or width of the second bridge portion 22 may be greater than the size and/or width of the first bridge portion 12. A curvature radius of a round portion of the second bridge portion 22 may be different from a curvature radius of a round portion of the first bridge portion 12. As an example, the curvature radius of a round portion of the second bridge portion 22 may be greater than the curvature radius of a round portion of the first bridge portion 12.

Each second island portion 21 may be connected to a plurality of second bridge portions 22. Each second island portion 21 may be connected to four second bridge portions 22. Two second bridge portions 22 may be arranged on two opposite sides of the second island portion 21 in the first direction (e.g., the x direction or the −x direction), respectively, and the remaining two second bridge portions 22 may be arranged on two opposite sides of the second island portion 21 in the second direction (e.g., the y direction or the −y direction), respectively. In an embodiment, four second bridge portions 22 may be connected to four lateral sides of the second island portion 21, respectively. Each second bridge portion 22 may be connected to the central portion of each lateral side of the second island portion 21.

The second island portions 21 in one row arranged in the first non-display area NDA1 may correspond to the first island portions 11 in a plurality of rows arranged in the display area DA. As an example, the second island portions 21 in one row arranged in the first non-display area NDA1 may correspond to the first island portions 11 in an (i)th row and the first island portions 11 in an (i+1)th row in the display area DA (here, i is a positive number greater than 0). In another embodiment, the second island portions 21 in one row may correspond to n rows of the first island portions 11 (here, n is a positive number equal to or greater than 3).

The non-display area, for example, the first non-display area NDA1 may include a first sub-non-display area SNDA1 in which the second island portions 21 and the second bridge portions 22 are arranged, and a second sub-non-display area SNDA2 between the first sub-non-display area SNDA1 and the display area DA. Third bridge portions 23 may be arranged in the second sub-non-display area SNDA2, where the third bridge portions 23 connects the display area DA to the first sub-non-display area SNDA1. One end of the third bridge portion 23 may be connected to the second island portion 21, and the other end of the third bridge portion 23 may be connected to the first island portion 11. As an example, one end of the third bridge portion 23 may be connected to the central portion of one side of the second island portion 21, and the other end of the third bridge portion 23 may be connected to the central portion of one lateral side of the first island portion 11.

The third bridge portion 23 may have a curved shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. In the second direction (e.g., the y direction or the −y direction), the third openings CS3 and the fourth openings CS4 having different shapes may be alternately arranged between the third bridge portions 23.

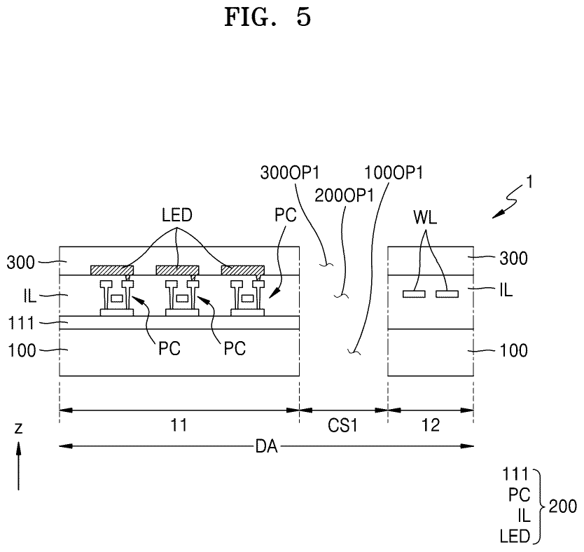

FIG. 5 is a schematic cross-sectional view of the first island portion 11 and the first bridge portion 12 arranged in the display area DA of the display apparatus 1 according to an embodiment.

Referring to FIG. 5, the first island portion 11 and the first bridge portion 12 arranged in the display area DA may be apart from each other with the first opening CS1 therebetween. The first island portion 11 may include light-emitting elements LED and a circuit, for example, a pixel driving circuit portion PC electrically connected to the light-emitting elements LED and configured to drive light-emitting elements. The bridge portion 12 may include a wiring WL electrically connected to the pixel driving circuit portions PC arranged on adjacent first island portions 11, respectively.

The first island portion 11 is described as follows, in which: a buffer layer 111 including an inorganic insulating material may be disposed on a substrate 100, and the pixel driving circuit portion PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and electrically connected to the pixel driving circuit portion PC. The light-emitting elements LED may be configured to emit light of different colors or emit light of the same color. In an embodiment, the light-emitting elements LED may be configured to emit red, green, and blue light, respectively. In an embodiment, the light-emitting elements LED may be configured to emit white light. In another embodiment, the light-emitting elements LED may be configured to emit red, green, blue, and white light, respectively.

The substrate 100 may include polymer resin such as polyethersulfone, polyarylate, polyetherimide, polyethylene naphthalate, polyethylene terephthalate, polyphenylene sulfide, polyimide, polycarbonate, cellulose tri acetate, and cellulose acetate propionate. In an embodiment, the substrate 100 may include a single layer including the polymer resin. In another embodiment, the substrate 100 may have a multi-layered structure including a base layer and a barrier layer, where the base layer includes the above polymer resin and the barrier layer includes an inorganic insulating material. The substrate 100 including the polymer resin is flexible, rollable, or bendable.

In an embodiment, although it is shown in FIG. 5 that three pixel driving circuit portions PC are arranged in the first island portion 11, and three light-emitting elements LED are connected to the pixel driving circuit portions PC, respectively, the embodiment is not limited thereto. In another embodiment, the number of pixel driving circuit portions PC and the number of light-emitting elements LED arranged in the first island portion 11 may be one, two, four, or more.

An encapsulation layer 300 may be disposed on the light-emitting element LED and may protect the light-emitting element LED from external force and/or moisture transmission. The encapsulation layer 300 may include an inorganic encapsulation layer and/or an organic encapsulation layer. In an embodiment, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In an embodiment, the encapsulation layer 300 may include urethane epoxy or acrylate. The encapsulation layer 300 may include a photosensitive material, for example, a photoresist.

The first bridge portion 12 is described as follows, in which: the insulating layer IL including an organic insulating material may be disposed on the substrate 100. Unlike the first island portion 11, the first bridge portion 12, which is relatively transformed much when the display apparatus 1 is stretched, may not include a layer including an inorganic insulating material that is prone to cracks.

In an embodiment, the substrate 100 corresponding to the first bridge portion 12 may have the same stack structure as the substrate 100 corresponding to the first island portion 11. In an embodiment, the substrate 100 corresponding to the first bridge portion 12 and the substrate 100 corresponding to the first island portion 11 may include polymer resin layers simultaneously formed during the same process. In another embodiment, the substrate 100 corresponding to the first bridge portion 12 may have a stack structure different from the substrate 100 corresponding to the first island portion 11. In an embodiment, the substrate 100 corresponding to the first bridge portion 12 may have a multi-layered structure including a base layer including polymer resin and a barrier layer including an inorganic insulating material, and the substrate 100 corresponding to the first bridge portion 12 may have a structure of a polymer resin layer without a layer including an inorganic insulating material.

As described above, the wirings WL of the first bridge portion 12 may be signal lines (e.g., a gate line, a data line, and the like) configured to provide electrical signals to transistors included in the pixel driving circuit portion PC of the first island portion 11, or voltage lines (e.g., a driving voltage line, an initialization voltage line, and the like) configured to provide voltages. The encapsulation layer 300 may be disposed also on the first bridge portion 12. In another embodiment, the encapsulation layer 300 may not be present in the first bridge portion 12.

Referring to FIGS. 4A to 4C, and 5C, the substrate 100 corresponding to the first island portion 11 and the substrate 100 corresponding to the first bridge portion 12 may be connected to each other. In other words, the plan views shown above in FIGS. 4A to 4C may be substantially same as the plan view of the substrate 100 of FIG. 5. In other words, the substrate 100 may include a region corresponding to the first island portion 11, a region corresponding to the first bridge portion 12, and an opening 1000P1 having a shape equal to the shape of the first opening CS1.

Similarly, the encapsulation layer 300 corresponding to the first island portion 11 and the encapsulation layer 300 corresponding to the first bridge portion 12 may be connected to each other. As an example, the plan views shown above in FIGS. 4A to 4C may be substantially same as the plan view of the encapsulation layer 300. In other words, the encapsulation layer 300 may include a region corresponding to the first island portion 11, a region corresponding to the first bridge portion 12, and an opening 3000P1 having a shape equal to the shape of the first opening CS1.

A circuit-light-emitting element layer 200 between the substrate 100 and the encapsulation layer 300 may include a buffer layer 111 the pixel driving circuit portion PC, the wiring WL, the insulating layer IL, and the light-emitting element LED. Similar to the substrate 100, the plan views shown above in FIGS. 4A to 4C may be substantially same as the plan view of the circuit-light-emitting element layer 200. In other words, the circuit-light-emitting element layer 200 may include an opening 2000P1 having a shape equal to the first opening CS1.

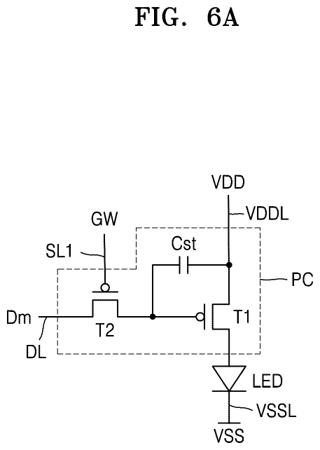

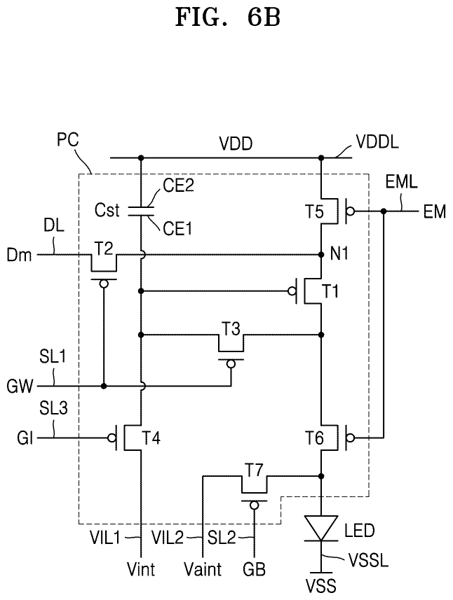

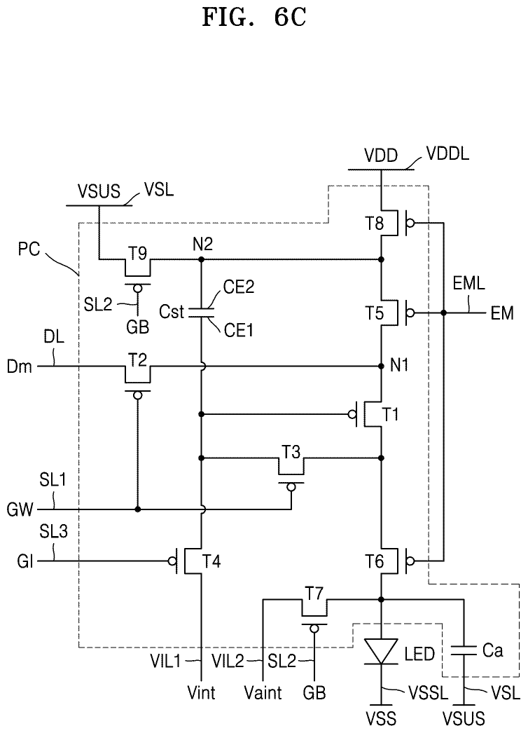

FIGS. 6A to 6C are equivalent circuit diagrams of a sub-pixel of the display apparatus 1 according to an embodiment, respectively.

Referring to FIG. 6A, the light-emitting element LED corresponding to the sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to the signal lines and the voltage lines. The signal lines may include a gate line such as a first scan line SL1, and a data line DL. The voltage lines may include a first voltage line VDDL.

The second transistor T2 may be electrically connected to the first scan line SL1 and the data line DL. The first scan line SL1 may be configured to provide a first scan signal GW1 to a gate electrode of the second transistor T2. The second transistor T2 may be configured to transfer a data signal Dm to the first transistor T1 according to a first scan signal GW1 input from the first scan line SL1, where the data signal Dm is input from the data line DL.

The storage capacitor Cst may be electrically connected to the second transistor T2 and a first voltage line VDDL and configured to store a voltage corresponding to a difference between a voltage transferred from the second transistor T2 and a first power voltage VDD supplied by the first voltage line VDDL.

The first transistor T1 is a driving transistor and may be configured to control a driving current flowing through the light-emitting element LED. The first transistor T1 may be connected to the first voltage line VDDL and the storage capacitor Cst. The first transistor T1 may be configured to control the driving current flowing from the first voltage line VDDL to the light-emitting element LED in response to a voltage value stored in the storage capacitor Cst. The light-emitting element LED may be configured to emit light having a preset brightness based on the driving current. A first electrode of the light-emitting element LED may be electrically connected to the first transistor T1, and a second electrode of the light-emitting element LED may be electrically connected to a second voltage line VSSL configured to supply a second power voltage VSS.

Although it is shown in FIG. 6A that the pixel driving circuit portion PC includes two transistors and one storage capacitor, the pixel driving circuit portion PC may include three or more transistors.

Referring to FIG. 6B, the pixel driving circuit portion PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit portion PC is electrically connected to the signal lines and the voltage lines. The signal lines may include the first scan line SL1, a second scan line SL2, a third scan line SL3, a fourth scan line SL4, the gate line such as an emission control line EML, and the data line DL. The voltage lines may include first and second initialization voltage lines VIL1 and VIL2 and the first voltage line VDDL.

The first voltage line VDDL may be configured to transfer the first power voltage VDD to the first transistor T1. The first initialization voltage line VIL1 may be configured to transfer the first initialization voltage Vint to the pixel driving circuit portion PC, where the first initialization voltage Vint initializes the first transistor T1. The second initialization voltage line VIL2 may be configured to transfer the second initialization voltage Vaint to the pixel driving circuit portion PC, where the second initialization voltage Vaint initializes the first electrode of the light-emitting element LED.

The first transistor T1 may be electrically connected to the first voltage line VDDL through the fifth transistor T5, and electrically connected to the light-emitting element LED through the sixth transistor T6. The first transistor T1 serves as the driving transistor, receives a data signal Dm, and supplies the driving current to the light-emitting element LED according to a switching operation of the second transistor T2.

The second transistor T2 serves as a data-write transistor and is electrically connected to the first scan line SL1 and the data line DL. The second transistor T2 may be connected to the first voltage line VDDL through the fifth transistor T5. The second transistor T2 is turned on according to a first scan signal GW transferred through the first scan line SL1, and performs a switching operation of transferring a data signal Dm to a first node N1, the data signal Dm being transferred through the data line DL.

The third transistor T3 is electrically connected to the first scan line SL1 and electrically connected to the light-emitting element LED through the sixth transistor T6. The third transistor T3 may be turned on according to a first scan signal GW to diode-connect the first transistor T1, where the first scan signal GW is transferred through the first scan line SL1.

The fourth transistor T4 serves as a first initialization transistor and is electrically connected to the first initialization voltage line VIL1. The fourth transistor T4 may be turned on according to a third scan signal GI to initialize a gate voltage of the first transistor T1 by transferring the initialization voltage Vint to the gate electrode of the first transistor T1, where the initialization voltage Vint is from the first initialization voltage line VIL1, and the third scan signal GI is transferred through the third scan line SL3. A third scan signal GI may correspond to a first scan signal of another pixel driving circuit portion arranged in a previous row of the relevant pixel driving circuit portion.

The fifth transistor T5 may be an operation control transistor, and the sixth transistor T6 may be an emission control transistor. The fifth transistor T5 and the sixth transistor T6 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VIL2, and the sixth transistor T6. The seventh transistor T7 is turned on according to a second scan signal GB transferred through the second scan line SL2, and is configured to transfer the second initialization voltage Vaint from the second initialization voltage line VIL2 to the first electrode of the light-emitting element LED, thereby initializing the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst and an auxiliary capacitor Ca.

The pixel driving circuit portion PC is electrically connected to the signal lines and the voltage lines. The signal lines may include the first scan line SL1, the second scan line SL2, the third scan line SL3, the fourth scan line SL4, the gate line such as the emission control line EML, and the data line DL. The voltage lines may include the first and second initialization voltage lines VIL1 and VIL2, a sustain voltage line VSL, and the first voltage line VDDL.

The first voltage line VDDL may be configured to transfer the first power voltage VDD to the first transistor T1. The first initialization voltage line VIL1 may be configured to transfer the first initialization voltage Vint to the pixel driving circuit portion PC, where the first initialization voltage Vint initializes the first transistor T1. The second initialization voltage line VIL2 may be configured to transfer the second initialization voltage Vaint to the pixel driving circuit portion PC, where the second initialization voltage Vaint initializes the first electrode of the light-emitting element LED. The sustain voltage line VSL may be configured to provide a sustain voltage VSUS to a second node N2, for example, the second electrode CE2 of the storage capacitor Cst during an initialization section and a data-write section.

The first transistor T1 may be electrically connected to the first voltage line VDDL through the fifth transistor T5 and the eighth transistor T8, and electrically connected to the light-emitting element LED through the sixth transistor T6. The first transistor T1 serves as the driving transistor, receives a data signal Dm, and may supply the driving current to the light-emitting element LED according to a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on according to a first scan signal GW transferred through the first scan line SL1 and may perform a switching operation of transferring a data signal Dm to the first node N1, where the data signal Dm is transferred through the data line DL.

The third transistor T3 is electrically connected to the first scan line SL1 and electrically connected to the light-emitting element LED through the sixth transistor T6. The third transistor T3 may be turned on according to a first scan signal GW to compensate for a threshold voltage of the first transistor T1 by diode-connecting the first transistor T1, where the first scan signal GW is transferred through the first scan line SL1.

The fourth transistor T4 is electrically connected to the third scan line SL3 and the first initialization voltage line VIL1, turned on according to a third scan signal GI transferred through the third scan line SL3, and initializes the voltage of the gate electrode of the first transistor T1 by transferring the initialization voltage Vint to the gate electrode of the first transistor T1, where the initialization voltage Vint is from the first initialization voltage line VIL1. A third scan signal GI may correspond to a first scan signal of another pixel driving circuit portion arranged in a previous row of the relevant pixel driving circuit portion.

The fifth transistor T5, the sixth transistor T6, and the eighth transistor T8 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VIL2, and the sixth transistor T6. The seventh transistor T7 is turned on according to a second scan signal GB transferred through the second scan line SL2, and is configured to transfer the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned according to a second scan signal GB transferred through the second scan line SL2 and configured to transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In an embodiment, during the initialization section and the data-write section, the eighth transistor T8 may be turned off and the ninth transistor T9 may be turned on, and during an emission section, the eighth transistor T8 may be turned on and the ninth transistor T9 may be turned off. Because, during the initialization section and the data-write section, the sustain voltage VSUS is transferred to the second node N2, uniformity in brightness of the display apparatus (e.g., long range uniformity (“LRU”)) corresponding to a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. While the seventh transistor T7 and the ninth transistor T9 are turned on, the auxiliary capacitor Ca stores and maintains a voltage corresponding to a voltage difference between the first electrode of the light-emitting element LED and the sustain voltage line VSL, thereby preventing a black brightness from rising when the sixth transistor T6 is turned off.

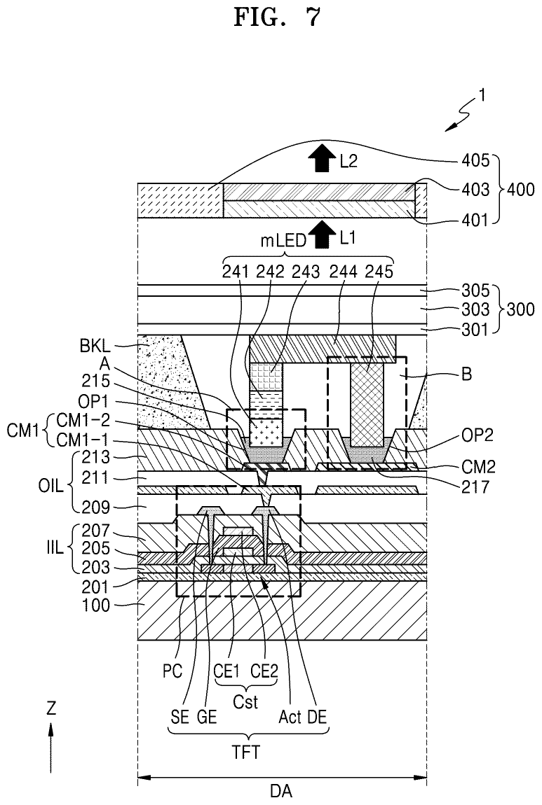

FIG. 7 is a schematic cross-sectional view of a portion of the display apparatus 1 according to an embodiment.

FIG. 7 may correspond to the display area DA (see FIG. 1) described with reference to FIGS. 1, 2A to 2E, 3, 4A to 4C, and 5. Specifically, FIG. 7 may correspond to the first island portion 11 (see FIG. 4A) described with reference to FIGS. 4A to 4C, and 5.

Referring to FIG. 7, the display apparatus 1 according to an embodiment may include the substrate 100, a buffer layer 201, the pixel driving circuit portion PC, an inorganic insulating layer IIL, an organic insulating layer OIL, a first connection electrode CM1, a second connection electrode CM2, a first conductive organic film 215, a second conductive organic film 217, an inorganic light-emitting diode mLED, a bank layer BKL, an encapsulation layer 300, and a filter panel 400.

The substrate 100 may include various materials. Specifically, the substrate 100 may include glass, metal, an organic material, or the like. In an embodiment, the substrate 100 may include a flexible material. As an example, the substrate 100 may include bendable, foldable, or rollable material. The flexible material of the substrate 100 may be ultra-thin glass, metal, or plastic. In the case where the substrate 100 includes plastic, the substrate 100 may include polyimide (“PI”). As another example, the substrate 100 may include a different kind of plastic material. The substrate 100 described with reference to FIG. 7 may correspond to the substrate 100 (see FIG. 5) described above with reference to FIG. 5.

The buffer layer 201 may be disposed on the substrate 100. The buffer layer 201 may prevent impurities from penetrating a semiconductor layer of a thin-film transistor. The buffer layer 201 described with reference to FIG. 7 may correspond to the buffer layer 111 (see FIG. 5) described above with reference to FIG. 5.

The inorganic insulating layer IIL may be disposed on the buffer layer 201. That is, the inorganic insulating layer IIL may be disposed over the substrate 100. The inorganic insulating layer IIL may include an inorganic insulating material including silicon oxide, silicon nitride, silicon oxynitride, aluminum oxide, titanium oxide, tantalum oxide, hafnium oxide, or the like. The inorganic insulating layer IIL may include a single layer or a multi-layer including the above materials.

The inorganic insulating layer IIL may include a gate insulating layer 203, a first interlayer-insulating layer 205, and a second interlayer-insulating layer 207. The first interlayer-insulating layer 205 may be disposed on the gate insulating layer 203, and the second interlayer-insulating layer 207 may be disposed on the first interlayer-insulating layer 205. That is, in the third direction (e.g., z direction) away from the substrate 100, the gate insulating layer 203, the first interlayer-insulating layer 205, and the second interlayer-insulating layer 207 may be sequentially disposed.

The pixel driving circuit portion PC may be disposed on the buffer layer 201. That is, the pixel driving circuit portion PC may be disposed over the substrate 100. The pixel driving circuit portion PC may include a thin-film transistor TFT and a storage capacitor Cst.

The thin-film transistor TFT may include a semiconductor layer Act, a gate electrode GE, a source electrode SE, and a drain electrode DE. In the present embodiment, although a top-gate type thin-film transistor in which the gate electrode GE is disposed over the semiconductor layer Act with the gate insulating layer 203 therebetween is shown, the thin-film transistor TFT may be a bottom-gate type thin-film transistor in another embodiment.

The semiconductor layer Act may include polycrystalline silicon. Alternatively, the semiconductor layer Act may include amorphous silicon, an oxide semiconductor, or an organic semiconductor. The gate electrode GE may include a low-resistance metal material. The gate electrode GE may include a conductive material including molybdenum (Mo), aluminum (Al), copper (Cu), titanium (Ti), or the like and have a single-layered structure or a multi-layered structure including the above materials.

The source electrode SE and the drain electrode DE may each include a material having high conductivity. The source electrode SE and the drain electrode DE may each include a conductive material including molybdenum (Mo), aluminum (Al), copper (Cu), titanium (Ti), or the like and include a single layer or a multi-layer including the above materials. In an embodiment, the source electrode SE and the drain electrode DE may each include a multi-layer of Ti/Al/Ti.

The storage capacitor Cst may include a lower electrode CE1 and an upper electrode CE2 overlapping each other with the first interlayer-insulating layer 205 therebetween in a plan view. The storage capacitor Cst may overlap the thin-film transistor TFT in a plan view. With regard to this, it is shown in FIG. 7 that the gate electrode GE of the thin-film transistor TFT serves as the lower electrode CE1 of the storage capacitor Cst. In another embodiment, the storage capacitor Cst may not overlap the thin-film transistor TFT in a plan view. The storage capacitor Cst may be covered by the second interlayer-insulating layer 207.

The pixel driving circuit portion PC described with reference to FIG. 7 may correspond to the pixel driving circuit portion PC (see FIG. 5) described with reference to FIG. 5.

The organic insulating layer OIL may be disposed on the inorganic insulating layer IIL. The organic insulating layer OIL may cover the pixel driving circuit portion PC. The organic insulating layer OIL may include an organic insulating material including a general-purpose polymer such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The organic insulating layer OIL may include a first organic insulating layer 209, a second organic insulating layer 211, and a third organic insulating layer 213. The first organic insulating layer 209 may cover the pixel driving circuit portion PC, the second organic insulating layer 211 may be disposed on the first organic insulating layer 209, and the third organic insulating layer 213 may be disposed on the second organic insulating layer 211. That is, in the third direction (e.g., z direction) away from the substrate 100, the first organic insulating layer 209, the second organic insulating layer 211, and the third organic insulating layer 213 may be sequentially disposed. All of the first organic insulating layer 209, the second organic insulating layer 211, and the third organic insulating layer 213 may include the same material or different materials. However, various modifications may be made.

To form the first organic insulating layer 209, the second organic insulating layer 211, and the third organic insulating layer 213, a liquid organic material is coated, then a mask process and a developing process may be performed to form a contact hole. As described above, because the first organic insulating layer 209, the second organic insulating layer 211, and the third organic insulating layer 213 are formed by curing the liquid organic material, an upper surface thereof may be formed approximately flat.

The inorganic insulating layer IIL and the organic insulating layer OIL described with reference to FIG. 7 may correspond to the insulating layer IL (see FIG. 5) described above with reference to FIG. 5.

The first connection electrode CM1 may be disposed on the organic insulating layer OIL and electrically connected to the pixel driving circuit portion PC. The first connection electrode CM1 may be electrically connected to the first voltage line VDDL (see FIG. 6A) described above with reference to FIGS. 6A to 6C.

The first connection electrode CM1 may include a 1-1 connection electrode CM1-1 and a 1-2 connection electrode CM1-2. The 1-1 connection electrode CM1-1 may be disposed between the first organic insulating layer 209 and the second organic insulating layer 211 and be in contact with the pixel driving circuit portion PC. The 1-2 connection electrode CM1-2 may be disposed on the 1-1 connection electrode CM1-1. The 1-2 connection electrode CM1-2 may be disposed between the second organic insulating layer 211 and the third organic insulating layer 213 and be in contact with the 1-1 connection electrode CM1-1.

The second connection electrode CM2 may be disposed on the organic insulating layer OIL. As an example, the second connection electrode CM2 may be disposed between the second organic insulating layer 211 and the third organic insulating layer 213. The second connection electrode CM2 may be connected to the second voltage line VSSL (see FIG. 6A) described above with reference to FIGS. 6A to 6C.

Although it is shown in FIG. 7 that the 1-1 connection electrode CM1-1 and the second connection electrode CM2 are disposed on different layers, and the 1-2 connection electrode CM1-2 and the second connection electrode CM2 are disposed on the same layer, this is just an example, and the arrangement of the first connection electrode CM1 and the second connection electrode CM2 is not limited thereto.

The organic insulating layer OIL may define the first opening OP1 and the second opening OP2 therein. The first opening OP1 and the second opening OP2 may be apart from each other.

The first opening OP1 may overlap the first connection electrode CM1 in a plan view. The first opening OP1 may pass through the organic insulating layer OIL to be in contact with the first connection electrode CM1. As an example, the first opening OP1 may pass through the third organic insulating layer 213. The first opening OP1 may be surrounded by the organic insulating layer OIL and the first connection electrode CM1.

The second opening OP2 may overlap the second connection electrode CM2 in a plan view. The second opening OP2 may pass through the organic insulating layer OIL to be in contact with the second connection electrode CM2. As an example, the second opening OP2 may pass through the third organic insulating layer 213. The second opening OP2 may be surrounded by the organic insulating layer OIL and the second connection electrode CM2.

The first conductive organic film 215 may be accommodated in the first opening OP1 to be electrically connected to the pixel driving circuit portion PC. As an example, the first conductive organic film 215 may be in contact with the first connection electrode CM1 electrically connected to the pixel driving circuit portion PC. That is, the first connection electrode CM1 may be disposed between the pixel driving circuit portion PC and the first conductive organic film 215 to connect the pixel driving circuit portion PC to the first conductive organic film 215.

The first conductive organic film 215 may include a carbon black material. In this case, the first connection electrode CM1 may include at least one of indium tin oxide (ITO), indium zinc oxide (IZO), and molybdenum (Mo), which are conductive to the first conductive organic film 215. As an example, the upper surface of the 1-2 connection electrode CM1-2 may be processed using least one of indium tin oxide (ITO), indium zinc oxide (IZO), and molybdenum (Mo).

The second conductive organic film 217 may be accommodated in the second opening OP2 and be in contact with the second connection electrode CM2. The second conductive organic film 217 may be disposed on the same layer as the first conductive organic film 215. The second connection electrode CM2 may be disposed between the pixel driving circuit portion PC and the second conductive organic film 217 and be connected to the second conductive organic film 217. The second conductive organic film 217 may be electrically connected to the second connection electrode CM2. Because the second opening OP2 accommodates the second conductive organic film 217, the second conductive organic film 217 may be apart from the first conductive organic film 215.

The second conductive organic film 217 includes the same material as the first conductive organic film 215, and the second connection electrode CM2 may include the same material as the first connection electrode CM1. The second conductive organic film 217 may include a carbon black material. In this case, the second connection electrode CM2 may include at least one of indium tin oxide (ITO), indium zinc oxide (IZO), and molybdenum (Mo), which are conductive to the second conductive organic film 217. As an example, the upper surface of the second connection electrode CM2 may be processed using least one of indium tin oxide (ITO), indium zinc oxide (IZO), and molybdenum (Mo).

The inorganic light-emitting diode mLED may be configured to emit first light L1 and may include a first electrode 241, a first semiconductor layer 242, an intermediate layer 243, a second semiconductor layer 244, and a second electrode 245.

The first semiconductor layer 242 may be disposed on the first electrode 241, the intermediate layer 243 may be disposed on the first semiconductor layer 242, and the second semiconductor layer 244 may be disposed on the intermediate layer 243. That is, the intermediate layer 243 may be disposed between the first semiconductor layer 242 and the second semiconductor layer 244. In addition, the second electrode 245 may be apart from the first electrode 241, and the second semiconductor layer 244 may be disposed on the second electrode 245. The first electrode 241, the first semiconductor layer 242, the intermediate layer 243, the second semiconductor layer 244, and the second electrode 245 may be electrically connected to each other.

At least a portion of the first electrode 241 may be accommodated in the first conductive organic film 215 and electrically connected to the first conductive organic film 215. In addition, at least a portion of the second electrode 245 may be accommodated in the second conductive organic film 217 and electrically connected to the second conductive organic film 217.

In an embodiment, the first semiconductor layer 242 may include a p-type semiconductor layer. The p-type semiconductor layer may include a semiconductor material with a composition formula of InxAlyGa1-x-yN (0≤x≤1, 0≤y≤1, 0≤x+y≤1), such as GaN, AlN, AlGaN, InGaN, InN, InAlGaN, AlInN, and the like, and may be doped with a p-type dopant such as Mg, Zn, Ca, Sr, Ba, and the like.

As an example, the second semiconductor layer 244 may include an n-type semiconductor layer. The n-type semiconductor layer may include a semiconductor material with a composition formula of InxAlyGa1-x-yN (0≤x≤1, 0≤y≤1, 0≤x+y≤1), such as GaN, AlN, AlGaN, InGaN, InN, InAlGaN, AlInN, and the like, and may be doped with n-type dopants such as Si, Ge, Sn, and the like.

The intermediate layer 243 is a region where electrons and holes recombine. As the electrons and holes recombine, the intermediate layer 233 transitions to a lower energy level and may generate light having a corresponding wavelength. In an embodiment, for example, the intermediate layer 243 may include a semiconductor material with a composition formula of InxAlyGa1-x-yN (0≤x≤1, 0≤y≤1, 0≤x+y≤1), and may be formed in a single quantum well structure or a multi quantum well structure (“MQW”). In addition, the intermediate layer 233 may include a quantum wire structure or a quantum dot structure.

Although it is described in FIG. 7 that the first semiconductor layer 242 includes a p-type semiconductor layer, and the second semiconductor layer 244 includes an n-type semiconductor layer, the embodiment is not limited thereto. In another embodiment, the first semiconductor layer 242 may include an n-type semiconductor layer, and the second semiconductor layer 244 may include a p-type semiconductor layer.

The bank layer BKL may be disposed on the organic insulating layer OIL. The bank layer BKL may include an insulating material and define an opening exposing the first opening OP1 and the second opening OP2. That is, the inorganic light-emitting diode mLED may be disposed in the opening disposed in the bank layer BKL.

The encapsulation layer 300 may be disposed on the inorganic light-emitting diode mLED and the bank layer BKL. The inorganic light-emitting diode mLED may be covered by the encapsulation layer 300. The encapsulation layer 300 may include at least one inorganic encapsulation layer and at least one organic encapsulation layer. In an embodiment, the encapsulation layer 300 may include a first inorganic encapsulation layer 301, an organic encapsulation layer 303, and a second inorganic encapsulation layer 305 that are sequentially stacked.

Each of the first inorganic encapsulation layer 301 and the second inorganic encapsulation layer 305 may include at least one inorganic insulating material. The inorganic insulating material may include aluminum oxide, tantalum oxide, hafnium oxide, zinc oxide, silicon oxide, silicon nitride, or/and silicon oxynitride. The organic encapsulation layer 303 may include a polymer-based material. The polymer-based material may include an acryl-based resin, an epoxy-based resin, polyimide, and polyethylene. Acrylic resins may include, for example, polymethyl methacrylate, polyacrylic acid, and the like.

The encapsulation layer 300 described with reference to FIG. 7 may correspond to the encapsulation layer 300 (see FIG. 5) described above with reference to FIG. 5.

The filter panel 400 may be disposed on the encapsulation layer 300. That is, the filter panel 400 may be disposed over the inorganic light-emitting diode mLED. The filter panel 400 may include a color converter 401, a color filter 403, and a light-blocking portion 405.

The color converter 401 may be configured to convert first light L1 to second light L2, where the first light L1 is emitted from the inorganic light-emitting diode mLED. The second light L2 may be light of a different or the same color as the first light L1. The first light L1 emitted from the inorganic light-emitting diode mLED may be blue light. The color converter 401 may be configured to convert blue first light L1 to red, green, or blue. The color filter 403 may be disposed on the color converter 401. The color filter 403 may have the same color as the light converted by the color converter 401. Accordingly, the second light L2 converted by the color converter 401 may be improved in its purity while passing through the color filter 403 and be emitted to the outside. The light-blocking portion 405 may surround the color converter 401 and the color filter 403. The light-blocking portion 405 may include a black matrix.

The color converter 401 may include quantum dots and scattering particles. A quantum dot may have a core-shell structure including a core and a shell, the core including a nano crystal, and the shell surrounding the core. A core of the quantum dot may be one of a Group II-Group VI compound, a Group III-Group V compound, a Group IV-Group VI compound, a Group IV element, a Group IV compound, and a combination thereof. Scattering particles may include TiO₂.

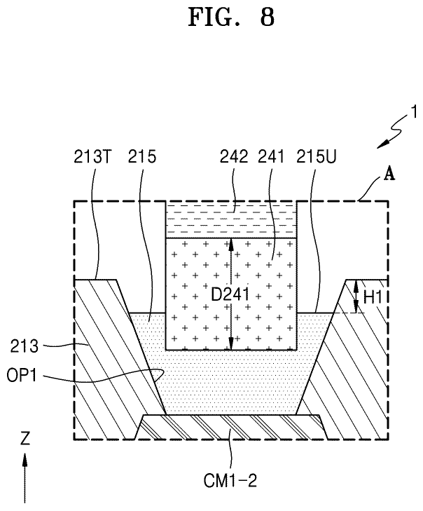

FIG. 8 is a schematic cross-sectional view of a portion of the display apparatus 1 according to an embodiment. Specifically, FIG. 8 is an enlarged view of a region A of FIG. 7.

Referring to FIGS. 7 and 8, the first conductive organic film 215 may be disposed in the first opening OP1. The first conductive organic film 215 may be in contact with the third organic insulating layer 213, the 1-2 connection electrode CM1-2, and the first electrode 241. The shape of the first conductive organic film 215 may correspond to the shape of the first opening OP1.

The upper surface 215U of the first conductive organic film 215 may be recessed from the top surface 213T of the organic insulating layer OIL. A height difference H1 in the third direction (e.g., z direction or −z direction) may be formed between the upper surface 215U of the first conductive organic film 215 and the top surface 213T of the organic insulating layer OIL. Here, the “top surface” is the highest upper surface among several upper surfaces with several heights when several upper surfaces with several heights exist. That is, a step difference may be formed between the first conductive organic film 215 and the third organic insulating layer 213. In this structure, the first conductive organic film 215 may not protrude from the organic insulating layer OIL.

At least a portion of the first electrode 241 may be accommodated in the first conductive organic film 215. A lower portion of the first electrode 241 may be in contact with the first conductive organic film 215. The lower surface of the first electrode 241 may be immersed in the first conductive organic film 215.

A thickness D241 of the first electrode 241 may be greater than the height difference H1 between the upper surface 215U of the first conductive organic film 215 and the top surface 213T of the organic insulating layer OIL in the third direction (e.g., z direction or −z direction). Accordingly, the first semiconductor layer 242 disposed on the first electrode 241 may be apart from the first conductive organic film 215. That is, only the first electrode 241 of the inorganic light-emitting diode may be in contact with the first conductive organic film 215.

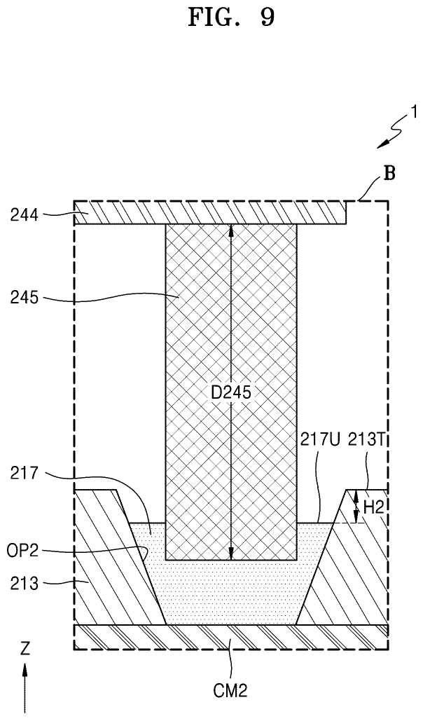

FIG. 9 is a schematic cross-sectional view of a portion of the display apparatus 1 according to an embodiment. Specifically, FIG. 9 is an enlarged view of a region B of FIG. 7.

Referring to FIGS. 7 and 9, the second conductive organic film 217 may be disposed in the second opening OP2. The second conductive organic film 217 may be in contact with the third organic insulating layer 213, the second connection electrode CM2, and the second electrode 245. The shape of the second conductive organic film 217 may correspond to the shape of the second opening OP2.

The upper surface 217U of the second conductive organic film 217 may be recessed from the top surface 213T of the organic insulating layer OIL. A height difference H2 may be formed between the upper surface 217U of the second conductive organic film 217 and the top surface 213T of the organic insulating layer OIL. That is, a step difference may be formed between the second conductive organic film 217 and the third organic insulating layer 213. In this structure, the second conductive organic film 217 may not protrude from the organic insulating layer OIL.

At least a portion of the second electrode 245 may be accommodated in the second conductive organic film 217. A lower portion of the second electrode 245 may be in contact with the second conductive organic film 217. The lower surface of the second electrode 245 may be immersed in the second conductive organic film 217.

A thickness D245 of the second electrode 245 may be greater than the height difference H2 between the upper surface 217U of the second conductive organic film 217 and the top surface 213T of the organic insulating layer OIL. Accordingly, the second semiconductor layer 244 disposed on the second electrode 245 may be apart from the second conductive organic film 217. That is, only the second electrode 245 of the inorganic light-emitting diode may be in contact with the second conductive organic film 217.

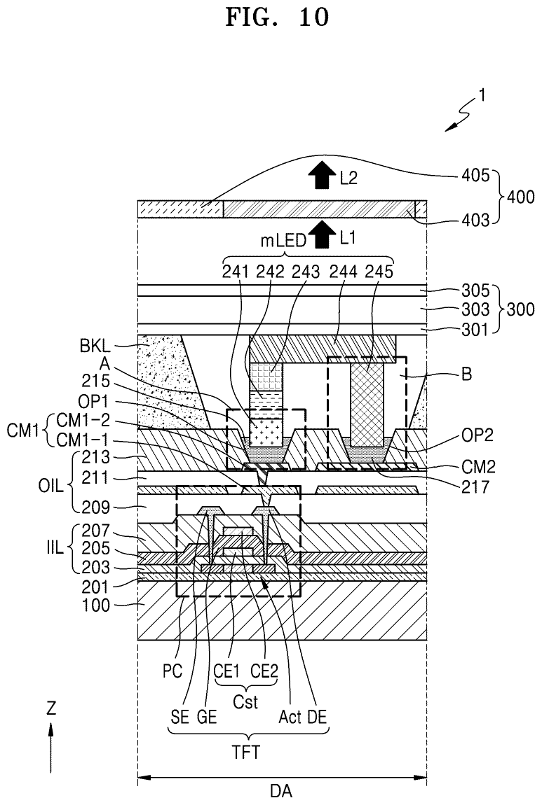

FIG. 10 is a schematic cross-sectional view of a portion of the display apparatus 1 according to an embodiment.

FIG. 10 may correspond to the display area DA (see FIG. 1) described with reference to FIGS. 1, 2A to 2E, 3, 4A to 4C, and 5. Specifically, FIG. 10 may correspond to the first island portion 11 (see FIG. 4A) described with reference to FIGS. 4A to 4C, and 5.

In FIG. 10, the same reference numerals as those of FIG. 7 denote the same members, and thus, repeated descriptions thereof are omitted.

Referring to FIG. 10, the display apparatus 1 according to an embodiment may include the substrate 100, the buffer layer 201, the pixel driving circuit portion PC, the inorganic insulating layer IIL, the organic insulating layer OIL, the first connection electrode CM1, the second connection electrode CM2, the first conductive organic film 215, the second conductive organic film 217, the inorganic light-emitting diode mLED, the bank layer BKL, the encapsulation layer 300, and the filter panel 400.

The substrate 100 may include various materials. The substrate 100 may include a flexible material. As an example, the substrate 100 may include bendable, foldable, or rollable material.

A buffer layer 201 may be disposed on the substrate 100. The buffer layer 201 may prevent impurities from penetrating a semiconductor layer of a thin-film transistor.

The inorganic insulating layer IIL may be disposed on the buffer layer 201. That is, the inorganic insulating layer IIL may be disposed over the substrate 100.

The inorganic insulating layer IIL may include the gate insulating layer 203, the first interlayer-insulating layer 205, and the second interlayer-insulating layer 207. The first interlayer-insulating layer 205 may be disposed on the gate insulating layer 203, and the second interlayer-insulating layer 207 may be disposed on the first interlayer-insulating layer 205.

The pixel driving circuit portion PC may be disposed on the buffer layer 201. That is, the pixel driving circuit portion PC may be disposed over the substrate 100. The pixel driving circuit portion PC may include the thin-film transistor TFT and the storage capacitor Cst.

The thin-film transistor TFT may include a semiconductor layer Act, a gate electrode GE, a source electrode SE, and a drain electrode DE. The semiconductor layer Act may include polycrystalline silicon. The gate electrode GE may include a low-resistance metal material. The source electrode SE and the drain electrode DE may each include a material having high conductivity.

The storage capacitor Cst may include a lower electrode CE1 and an upper electrode CE2 overlapping each other with a first interlayer-insulating layer 205 therebetween in a plan view. The storage capacitor Cst may overlap the thin-film transistor TFT in a plan view.

The organic insulating layer OIL may be disposed on the inorganic insulating layer IIL. The organic insulating layer OIL may cover the pixel driving circuit portion PC. The organic insulating layer OIL may include the first organic insulating layer 209, the second organic insulating layer 211, and the third organic insulating layer 213. The first organic insulating layer 209 may cover the pixel driving circuit portion PC, the second organic insulating layer 211 may be disposed on the first organic insulating layer 209, and the third organic insulating layer 213 may be disposed on the second organic insulating layer 211.

The first connection electrode CM1 may be disposed on the organic insulating layer OIL and electrically connected to the pixel driving circuit portion PC. The first connection electrode CM1 may be connected to the first voltage line VDDL (see FIG. 6C) described above with reference to FIGS. 6A to 6C.

The first connection electrode CM1 may include the 1-1 connection electrode CM1-1 and the 1-2 connection electrode CM1-2. The 1-1 connection electrode CM1-1 may be disposed between the first organic insulating layer 209 and the second organic insulating layer 211 and be in contact with the pixel driving circuit portion PC. The 1-2 connection electrode CM1-2 may be disposed on the 1-1 connection electrode CM1-1. The 1-2 connection electrode CM1-2 may be disposed between the second organic insulating layer 211 and the third organic insulating layer 213 and be in contact with the 1-1 connection electrode CM1-1.

The second connection electrode CM2 may be disposed on the organic insulating layer OIL. As an example, the second connection electrode CM2 may be disposed between the second organic insulating layer 211 and the third organic insulating layer 213. The second connection electrode CM2 may be connected to the second voltage line VSSL (see FIG. 6C) described above with reference to FIGS. 6A to 6C.

The organic insulating layer OIL may define the first opening OP1 and the second opening OP2 therein. The first opening OP1 and the second opening OP2 may be apart from each other.

The first opening OP1 may overlap the first connection electrode CM1 in a plan view. The first opening OP1 may pass through the organic insulating layer OIL to be in contact with the first connection electrode CM1. As an example, the first opening OP1 may pass through the third organic insulating layer 213. The first opening OP1 may be surrounded by the organic insulating layer OIL and the first connection electrode CM1.

The second opening OP2 may overlap the second connection electrode CM2 in a plan view. The second opening OP2 may pass through the organic insulating layer OIL to be in contact with the second connection electrode CM2. As an example, the second opening OP2 may pass through the third organic insulating layer 213. The second opening OP2 may be surrounded by the organic insulating layer OIL and the second connection electrode CM2.

The first conductive organic film 215 may be accommodated in the first opening OP1 to be electrically connected to the pixel driving circuit portion PC. As an example, the first conductive organic film 215 may be in contact with the first connection electrode CM1 electrically connected to the pixel driving circuit portion. That is, the first connection electrode CM1 may be disposed between the pixel driving circuit portion PC and the first conductive organic film 215 to connect the pixel driving circuit portion PC to the first conductive organic film 215.

The first conductive organic film 215 may include a carbon black material. In this case, the first connection electrode CM1 may include at least one of indium tin oxide (ITO), indium zinc oxide (IZO), and molybdenum (Mo), which are conductive to the first conductive organic film 215.

The second conductive organic film 217 may be accommodated in the second opening OP2 and be in contact with the second connection electrode CM2. The second conductive organic film 217 may be disposed on the same layer as the first conductive organic film 215. The second connection electrode CM2 may be disposed between the pixel driving circuit portion PC and the second conductive organic film 217 and be connected to the second conductive organic film 217. The second conductive organic film 217 may be electrically connected to the second connection electrode CM2. Because the second opening OP2 accommodates the second conductive organic film 217, the second conductive organic film 217 may be apart from the first conductive organic film 215.

The second conductive organic film 217 includes the same material as the first conductive organic film 215, and the second connection electrode CM2 may include the same material as the first connection electrode CM1. The second conductive organic film 217 may include a carbon black material. In this case, the second connection electrode CM2 may include at least one of indium tin oxide (ITO), indium zinc oxide (IZO), and molybdenum (Mo), which are conductive to the second conductive organic film 217.

The inorganic light-emitting diode mLED may be configured to emit first light L1 and may include the first electrode 241, the first semiconductor layer 242, the intermediate layer 243, the second semiconductor layer 244, and the second electrode 245.

The first semiconductor layer 242 may be disposed on the first electrode 241, the intermediate layer 243 may be disposed on the first semiconductor layer 242, and the second semiconductor layer 244 may be disposed on the intermediate layer 243. That is, the intermediate layer 243 may be disposed between the first semiconductor layer 242 and the second semiconductor layer 244. In addition, the second electrode 245 may be apart from the first electrode 241, and the second semiconductor layer 244 may be disposed on the second electrode 245. The first electrode 241, the first semiconductor layer 242, the intermediate layer 243, the second semiconductor layer 244, and the second electrode 245 may be electrically connected to each other.

At least a portion of the first electrode 241 may be accommodated in the first conductive organic film 215 and electrically connected to the first conductive organic film 215. In addition, at least a portion of the second electrode 245 may be accommodated in the second conductive organic film 217 and electrically connected to the second conductive organic film 217.

The bank layer BKL may be disposed on the organic insulating layer OIL. The bank layer BKL may include an insulating material and include the opening exposing the first opening OP1 and the second opening OP2. That is, the inorganic light-emitting diode mLED may be disposed in the opening disposed in the bank layer BKL.

The encapsulation layer 300 may be disposed on the inorganic light-emitting diode mLED and the bank layer BKL. The inorganic light-emitting diode mLED may be covered by the encapsulation layer 300. The encapsulation layer 300 may include at least one inorganic encapsulation layer and at least one organic encapsulation layer. In an embodiment, the encapsulation layer 300 may include the first inorganic encapsulation layer 301, the organic encapsulation layer 303, and the second inorganic encapsulation layer 305 that are sequentially stacked.

The filter panel 400 may be disposed on the encapsulation layer 300. That is, the filter panel 400 may be disposed over the inorganic light-emitting diode mLED. The filter panel 400 may include the color filter 403 and the light-blocking portion 405.

The first light L1 emitted by the inorganic light-emitting diode mLED may be red, green, or blue light. The color filter 403 may have the same color as the first light L1 emitted by the inorganic light-emitting diode mLED. Accordingly, the first light L1 emitted by the inorganic light-emitting diode mLED may be improved in its purity while passing through the color filter 403 and be emitted to the outside. The light-blocking portion 405 may surround the color filter 403. The light-blocking portion 405 may include a black matrix.

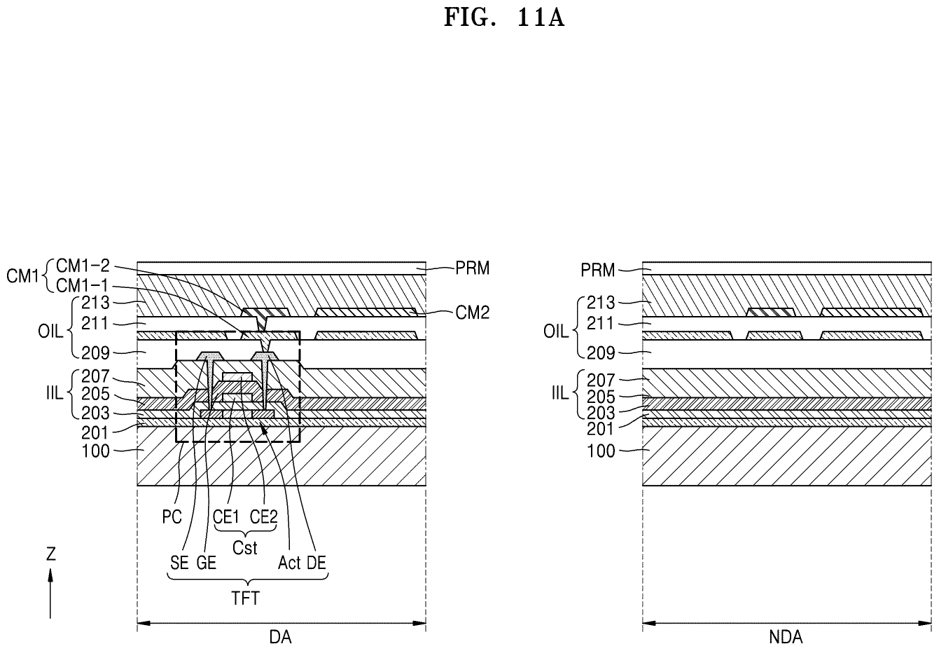

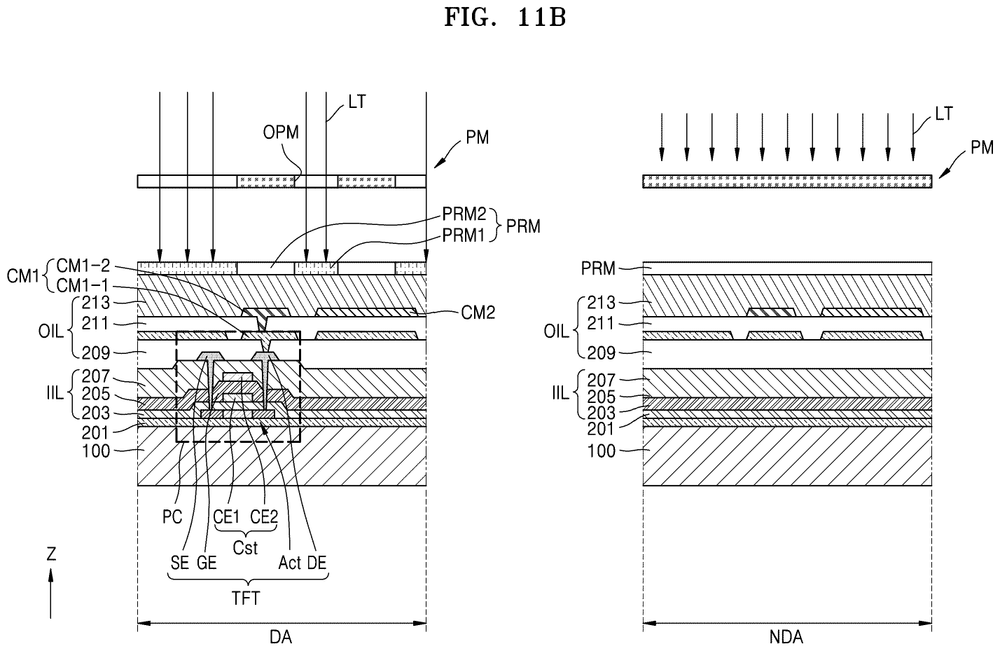

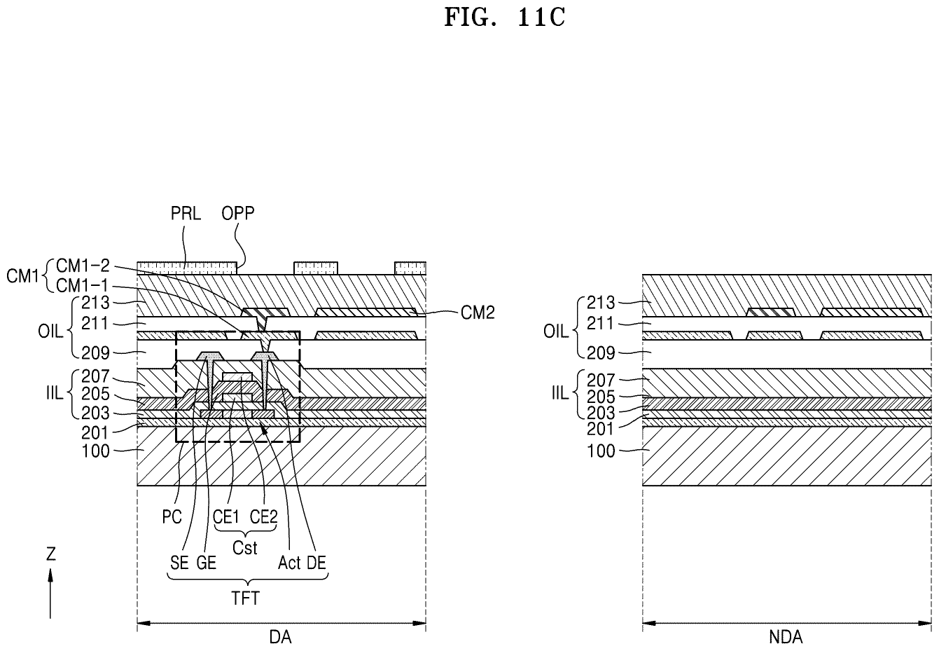

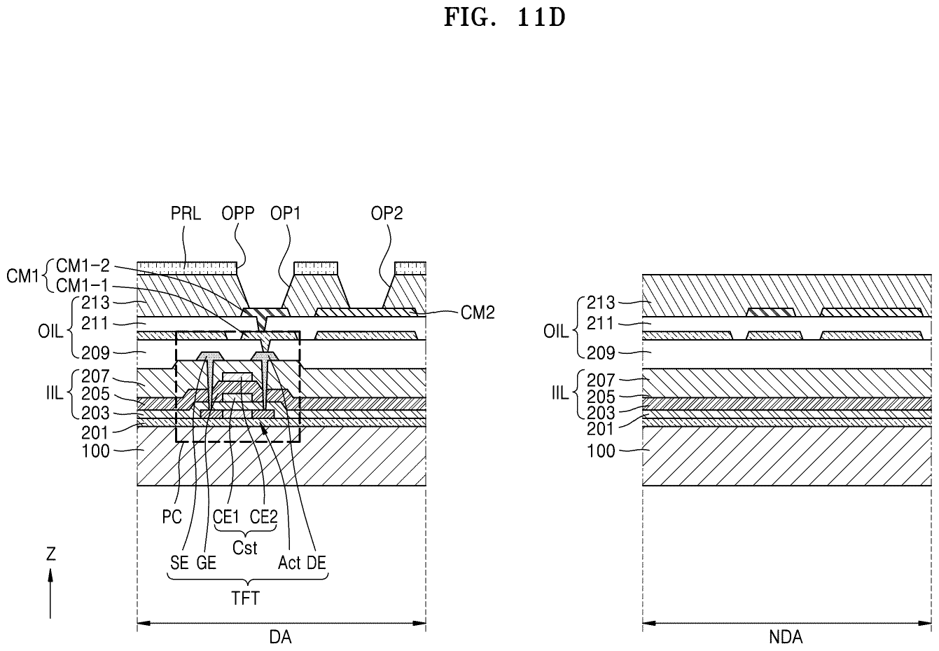

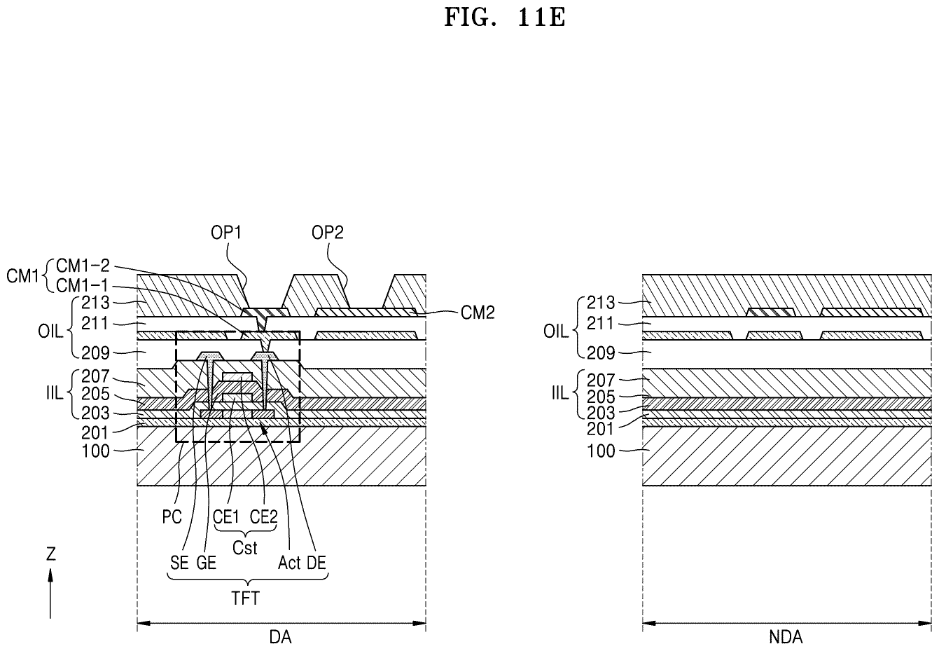

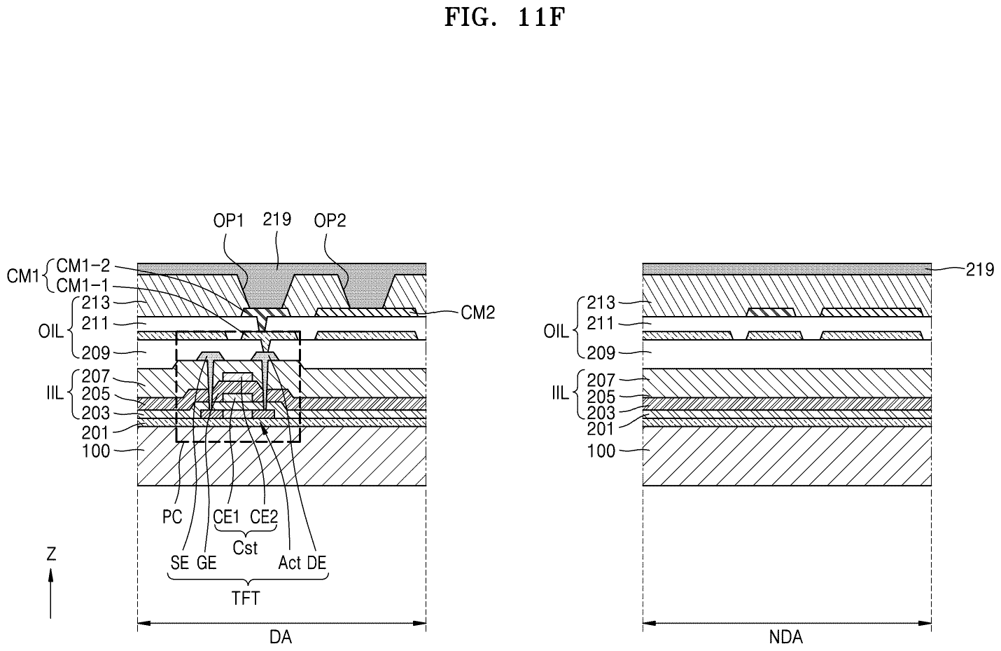

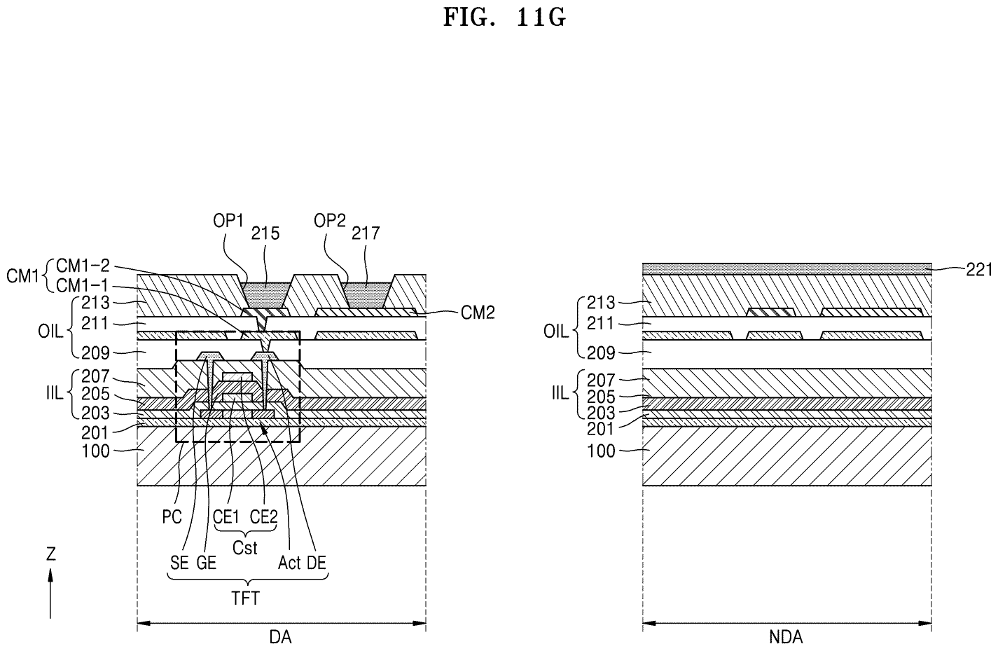

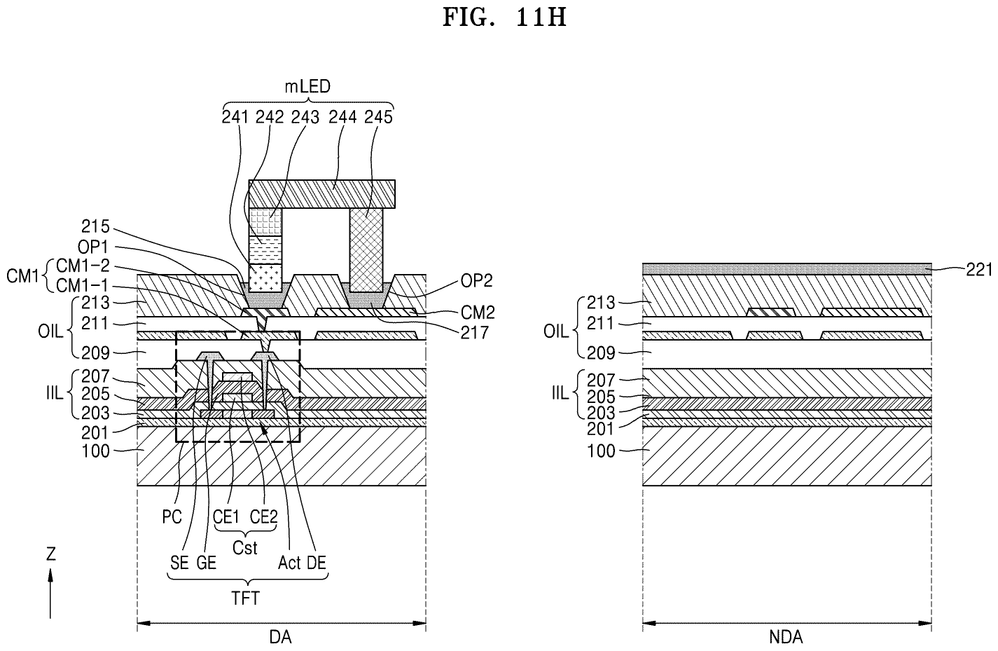

FIGS. 11A to 11H are schematic cross-sectional views of the display apparatus 1 according to an embodiment.

Referring to FIGS. 11A to 11H, a method of manufacturing the display apparatus 1 may be described.

In FIGS. 11A to 11H, the same reference numerals as those of FIGS. 7 to 10 denote the same members, and thus, repeated descriptions thereof are omitted.

First, referring to FIGS. 11A to 11E, the method of manufacturing the display apparatus 1 may include disposing the pixel driving circuit portion PC over the substrate 100, disposing the organic insulating layer OIL on the pixel driving circuit portion PC, etching the organic insulating layer OIL to form the first opening OP1, and etching the organic insulating layer OIL to form the second opening OP2 apart from the first opening OP1.

The pixel driving circuit portion PC may be disposed on the substrate 100 in the display area DA. The organic insulating layer OIL may be disposed on the pixel driving circuit portion PC. The organic insulating layer OIL may be disposed on the substrate 100 in the display area DA and the non-display area NDA to cover the pixel driving circuit portion PC. The organic insulating layer OIL may be disposed on the inorganic insulating layer IIL in the display area DA and the non-display area NDA.

Each of the etching of the organic insulating layer OIL to form the first opening OP1, and the etching of the organic insulating layer OIL to form the second opening OP2 may include dry-etching the organic insulating layer OIL using an etching gas. Specifically, the etching of the organic insulating layer OIL to form the first opening OP1, and the etching of the organic insulating layer OIL to form the second opening OP2 may be performed simultaneously.

Referring to FIG. 11A, a photoresist material PRM may be disposed on the organic insulating layer OIL. Specifically, the photoresist material PRM may be arranged in both the display area DA and the non-display area NDA of the display apparatus 1. The photoresist material PRM may be a photosensitive material.

Referring to FIG. 11B, a photo mask PM may be disposed over the photoresist material PRM. The photo mask PM may include a mask opening OPM and be arranged in both the display area DA and the non-display area NDA of the display apparatus 1. Light LT may be irradiated from the photo mask PM toward the photoresist material PRM. That is, the photoresist material PRM may be exposed. As an example, the light LT may be an ultraviolet ray. A portion of the light LT may be blocked by the photo mask PM, and the rest of the light LT may pass through mask opening OPM to reach the photoresist material PRM.

The photoresist material PRM arranged in the display area DA may be divided into a first portion PRM1 and a second portion PRM2, where the first portion PRM1 is in contact with the light LT, and the second portion PRM2 is not in contact with the light LT. The solubility of the first portion PRM1 of the photoresist material PRM may decrease. That is, the first portion PRM1 of the photoresist material PRM may be cured by light LT. All of the photoresist material PRM arranged in the non-display area NDA may not be in contact with the light LT. That is, the photoresist material PRM arranged in the non-display area NDA may not be cured by the light LT.

Referring to FIG. 11C, the photoresist material PRM (see FIG. 11B) may be developed into a patterned photoresist layer PRL. In the display area DA, the first portion PRM1 that is cured (see FIG. 11B) of the photoresist material PRM (see FIG. 11B) may remain, and the second portion PRM2 (see FIG. 11B) that is not cured may be removed. Finally, in the display area DA, the photoresist layer PRL may include a photo opening OPP. In the non-display area NDA, the photoresist material PRM (see FIG. 11B) may be removed.

Referring to FIG. 11D, the organic insulating layer OIL overlapping the photo opening OPP of the photoresist layer PRL in a plan view may be dry-etched by an etching gas. That is, the organic insulating layer OIL only in the display area DA of the display apparatus 1 may be etched. While the organic insulating layer OIL is dry-etched, the first opening OP1 and the second opening OP2 may be formed in the organic insulating layer OIL. The first connection electrode CM1 may be exposed from the organic insulating layer OIL through the first opening OP1, and the second connection electrode CM2 may be exposed from the organic insulating layer OIL through the second opening OP2.

Referring to FIG. 11E, the photoresist layer PRL (see FIG. 11D) may be removed. Finally, the first opening OP1 and the second opening OP2 may be formed in the organic insulating layer OIL.

Although it is described with reference to FIGS. 11A to 11E that a negative photoresist material whose solubility decreases when being in contact with the light LT is used, this is just an example, a positive photoresist material whose solubility increases when being in contact with the light LT may be used.

Because the organic insulating layer OIL is etched in FIGS. 11A to 11E and dry etching using an etching gas may be performed, the shape and the size of the first opening OP1 and the second opening OP2 may be precisely adjusted. That is, in the operation, detailed patterning of the organic insulating layer OIL exposing the first connection electrode CM1 and the second connection electrode CM2 may be performed.

Referring to FIGS. 11F to 11G, the method of manufacturing the display apparatus 1 may include disposing the first conductive organic film 215 in the first opening OP1 and disposing the second conductive organic film 217 in the second opening OP2. Specifically, the disposing of the first conductive organic film 215 in the first opening OP1 and the disposing of the second conductive organic film 217 in the second opening OP2 may be simultaneously performed.

First, referring to FIG. 11F, each of the disposing of the first conductive organic film 215 in the first opening OP1 and the disposing of the second conductive organic film 217 in the second opening OP2 may include disposing a conductive organic film material 219 on the organic insulating layer OIL, soft-baking the conductive organic film material 219, and drying the conductive organic film material 219.

The conductive organic film material 219 may be arranged in the display area DA and the non-display area NDA of the display apparatus 1 entirely. The conductive organic film material 219 may include a carbon black material. The conductive organic film material 219 arranged in the display area DA may be accommodated in the first opening OP1 and the second opening OP2 and be in contact with the first connection electrode CM1 and the second connection electrode CM2.

The soft-baking and the drying may be performed on the display area DA and the non-display area NDA of the display apparatus 1 entirely. In the soft-baking, the photoresist material PRM may be cured by receiving heat. In the drying, the photoresist material PRM may be dried inside a vacuum chamber. Accordingly, in the drying, the solvent of the photoresist material PRM may be removed by evaporation.

Referring to FIG. 11G, each of the disposing of the first conductive organic film 215 in the first opening OP1 and the disposing of the second conductive organic film 217 in the second opening OP2 may include developing the conductive organic film material 219.

When the conductive organic film material 219 is developed, the conductive organic film material 219 may be removed from the display area DA of the display apparatus 1, except for the first conductive organic film 215 disposed in the first opening OP1 and the second conductive organic film 217 disposed in the second opening OP2.

In addition, in the non-display area NDA of the display apparatus 1, the conductive organic film material 219 may not be removed, or the degree of removal may be small compared to the display area DA. In the non-display area NDA, the degree of removal of the conductive organic film material 219 may be determined by the soft-baking operation and the drying operation described with reference to FIG. 11F. Accordingly, a conductive organic film layer 221 covering the organic insulating layer OIL may be formed on the organic insulating layer OIL in the non-display area NDA.

The conductive organic film layer 221 may block light in the non-display area NDA. Because, during the process of disposing the first conductive organic film 215 and the second conductive organic film 217 in the display area DA, the conductive organic film layer 221 for blocking light is simultaneously disposed in the non-display area NDA, the manufacturing process of the display apparatus 1 may be simplified.

Referring to FIG. 11H, the method of manufacturing the display apparatus 1 may include disposing the inorganic light-emitting diode mLED.

The disposing of the inorganic light-emitting diode mLED may include accommodating at least a portion of the first electrode 241 in the first conductive organic film 215, and accommodating at least a portion of the second electrode 245 in the second conductive organic film 217.

Specifically, the accommodating of at least a portion of the first electrode 241 in the first conductive organic film 215, and the accommodating of at least a portion of the second electrode 245 in the second conductive organic film 217 may be simultaneously performed.

The accommodating of at least a portion of the first electrode 241 in the first conductive organic film 215 may include pressing the first electrode 241 to the first conductive organic film 215 and heating the first conductive organic film 215. The accommodating of at least a portion of the second electrode 245 in the second conductive organic film 217 may include pressing the second electrode 245 to the second conductive organic film 217 and heating the second conductive organic film 217.

Specifically, the pressing of the first electrode 241 to the first conductive organic film 215 and the pressing of the second electrode 245 to the second conductive organic film 217 may be simultaneously performed. In addition, the heating of the first conductive organic film 215 and the heating of the second conductive organic film 217 may be simultaneously performed.

The heating of the first conductive organic film 215 may include heating the first conductive organic film 215 to about 120 degrees in Celsius (° C.) to about 140° C. In addition, the heating of the second conductive organic film 217 may include heating the second conductive organic film 217 to about 120° C. to about 140° C. That is, the first conductive organic film 215 and the second conductive organic film 217 may be heated to the same temperature.

Because the first electrode 241 is attached to the first conductive organic film 215, and the second electrode 245 is attached to the second conductive organic film 217, temperature and pressure applied to the display apparatus 1 may be reduced. In other words, because each of the first electrode 241 and the second electrode 245 is pressed to the organic material including carbon black, not an inorganic material, temperature and pressure required for attaching the first electrode 241 and the second electrode 245 may be reduced. Accordingly, thermal transformation or destruction of at least one of the substrate 100, the inorganic insulating layer IIL, the organic insulating layer OIL, and the inorganic light-emitting diode mLED due to high temperature may be reduced.

Due to a height difference between the top surface 213T of the organic insulating layer OIL and the first conductive organic film 215, overflowing of the first conductive organic film 215 from the first opening OP1 during the process of accommodating at least a portion of the first electrode 241 in the first conductive organic film 215 may be reduced. In addition, due to a height difference between the top surface 213T of the organic insulating layer OIL and the second conductive organic film 217, overflowing of the second conductive organic film 217 from the second opening OP2 during the process of accommodating at least a portion of the second electrode 245 in the second conductive organic film 217 may be reduced.

The method of manufacturing the display apparatus 1 may include disposing the encapsulation layer 300 (see FIG. 7) on the inorganic light-emitting diode mLED and disposing the filter panel 400 (see FIG. 7) over the encapsulation layer 300 (see FIG. 7), which are described with reference to FIGS. 7 and 9. Accordingly, detailed descriptions thereof are omitted.

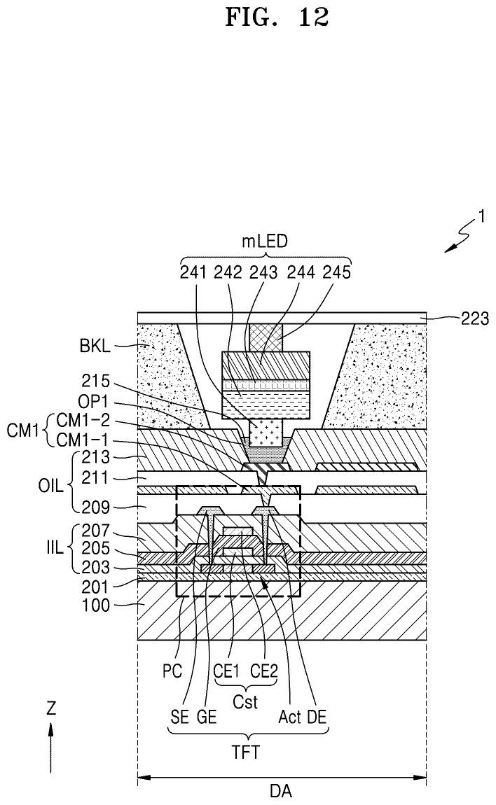

FIG. 12 is a schematic cross-sectional view of a portion of the display apparatus 1 according to an embodiment.

FIG. 12 may correspond to the display area DA (see FIG. 1) described with reference to FIGS. 1, 2A to 2E, 3, 4A to 4C, and 5. Specifically, FIG. 12 may correspond to the first island portion 11 (see FIG. 4A) described with reference to FIGS. 4A to 4C, and 5.

In FIG. 12, the same reference numerals as those of FIGS. 7 and 10 denote the same members, and thus, repeated descriptions thereof are omitted.

Referring to FIG. 12, the display apparatus 1 according to an embodiment may include the substrate 100, the buffer layer 201, the pixel driving circuit portion PC, the inorganic insulating layer IIL, the organic insulating layer OIL, the first connection electrode CM1, the first conductive organic film 215, the inorganic light-emitting diode mLED, the bank layer BKL, and an opposite electrode 223.

The substrate 100 may include various materials. The substrate 100 may include a flexible material. As an example, the substrate 100 may include bendable, foldable, or rollable material.

The buffer layer 201 may be disposed on the substrate 100. The buffer layer 201 may prevent impurities from penetrating a semiconductor layer of a thin-film transistor.

The inorganic insulating layer IIL may be disposed on the buffer layer 201. That is, the inorganic insulating layer IIL may be disposed over the substrate 100.

The inorganic insulating layer IIL may include a gate insulating layer 203, a first interlayer-insulating layer 205, and a second interlayer-insulating layer 207. The first interlayer-insulating layer 205 may be disposed on the gate insulating layer 203, and the second interlayer-insulating layer 207 may be disposed on the first interlayer-insulating layer 205.

The pixel driving circuit portion PC may be disposed on the buffer layer 201. That is, the pixel driving circuit portion PC may be disposed on over the substrate 100. The pixel driving circuit portion PC may include a thin-film transistor TFT and a storage capacitor Cst.

The thin-film transistor TFT may include a semiconductor layer Act, a gate electrode GE, a source electrode SE, and a drain electrode DE. The semiconductor layer Act may include polycrystalline silicon. The gate electrode GE may include a low-resistance metal material. The source electrode SE and the drain electrode DE may each include a material having high conductivity.

The storage capacitor Cst may include a lower electrode CE1 and an upper electrode CE2 overlapping each other with a first interlayer-insulating layer 205 therebetween in a plan view. The storage capacitor Cst may overlap the thin-film transistor TFT in a plan view.

The organic insulating layer OIL may be disposed on the inorganic insulating layer IIL. The organic insulating layer OIL may cover the pixel driving circuit portion PC. The organic insulating layer OIL may include the first organic insulating layer 209, the second organic insulating layer 211, and the third organic insulating layer 213. The first organic insulating layer 209 may cover the pixel driving circuit portion PC, the second organic insulating layer 211 may be disposed on the first organic insulating layer 209, and the third organic insulating layer 213 may be disposed on the second organic insulating layer 211.

The first connection electrode CM1 may be disposed on the organic insulating layer OIL and electrically connected to the pixel driving circuit portion PC. The first connection electrode CM1 may be connected to the first voltage line VDDL (see FIG. 6C) described above with reference to FIGS. 6A to 6C.

The first connection electrode CM1 may include the 1-1 connection electrode CM1-1 and the 1-2 connection electrode CM1-2. The 1-1 connection electrode CM1-1 may be disposed between the first organic insulating layer 209 and the second organic insulating layer 211 and be in contact with the pixel driving circuit portion PC. The 1-2 connection electrode CM1-2 may be disposed on the 1-1 connection electrode CM1-1. The 1-2 connection electrode CM1-2 may be disposed between the second organic insulating layer 211 and the third organic insulating layer 213 and be in contact with the 1-1 connection electrode CM1-1.

The organic insulating layer OIL may include the first opening OP1. The first opening OP1 may overlap the first connection electrode CM1 in a plan view. The first opening OP1 may pass through the organic insulating layer OIL to be in contact with the first connection electrode CM1. As an example, the first opening OP1 may pass through the third organic insulating layer 213. The first opening OP1 may be surrounded by the organic insulating layer OIL and the first connection electrode CM1.

The first conductive organic film 215 may be accommodated in the first opening OP1 to be electrically connected to the pixel driving circuit portion PC. As an example, the first conductive organic film 215 may be in contact with the first connection electrode CM1 electrically connected to the pixel driving circuit portion PC. That is, the first connection electrode CM1 may be disposed between the pixel driving circuit portion PC and the first conductive organic film 215 to connect the pixel driving circuit portion PC to the first conductive organic film 215.

The first conductive organic film 215 may include a carbon black material. In this case, the first connection electrode CM1 may include at least one of indium tin oxide (ITO), indium zinc oxide (IZO), and molybdenum (Mo), which are conductive to the first conductive organic film 215.

The inorganic light-emitting diode mLED may include the first electrode 241, the first semiconductor layer 242, the intermediate layer 243, the second semiconductor layer 244, and the second electrode 245.

The first semiconductor layer 242 may be disposed on the first electrode 241, the intermediate layer 243 may be disposed on the first semiconductor layer 242, the second semiconductor layer 244 may be disposed on the intermediate layer 243, and the second electrode 245 may be disposed on the second semiconductor layer 244. That is, the intermediate layer 243 may be disposed between the first semiconductor layer 242 and the second semiconductor layer 244. The first electrode 241, the first semiconductor layer 242, the intermediate layer 243, the second semiconductor layer 244, and the second electrode 245 may be electrically connected to each other.

At least a portion of the first electrode 241 may be accommodated in the first conductive organic film 215 and electrically connected to the first conductive organic film 215. The bank layer BKL may be disposed on the organic insulating layer OIL. The bank layer BKL may include an insulating material and include the opening exposing the first opening OP1. That is, the inorganic light-emitting diode mLED may be disposed in the opening disposed in the bank layer BKL.

The opposite electrode 223 may be disposed on the inorganic light-emitting diode mLED. The opposite electrode 223 may be supported by the bank layer BKL and electrically connected to the second electrode 245 of the inorganic light-emitting diode mLED. The opposite electrode 223 may be electrically connected to the second voltage line VSSL (see FIG. 6A) configured to supply the second power voltage VSS (see FIG. 6A) described above with reference to FIGS. 6A to 6C.

The encapsulation layer 300 (see FIG. 7) may be disposed on the opposite electrode 223, and the filter panel 400 (see FIG. 7) may be disposed on the encapsulation layer 300 (see FIG. 7), which are described with reference to FIGS. 7 and 9. Accordingly, detailed description thereof are omitted.

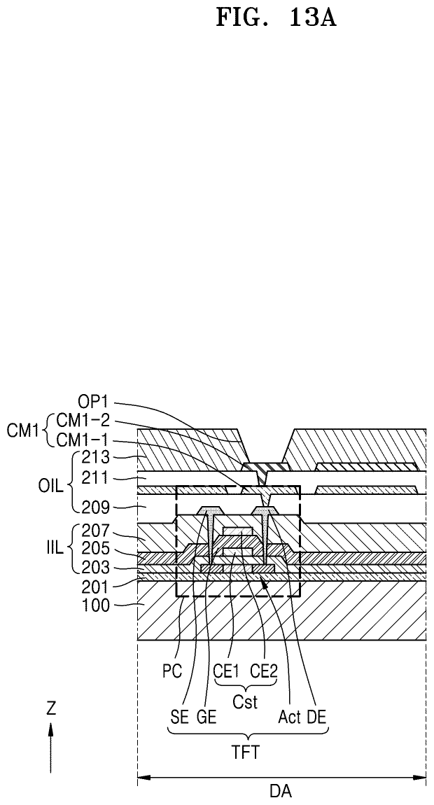

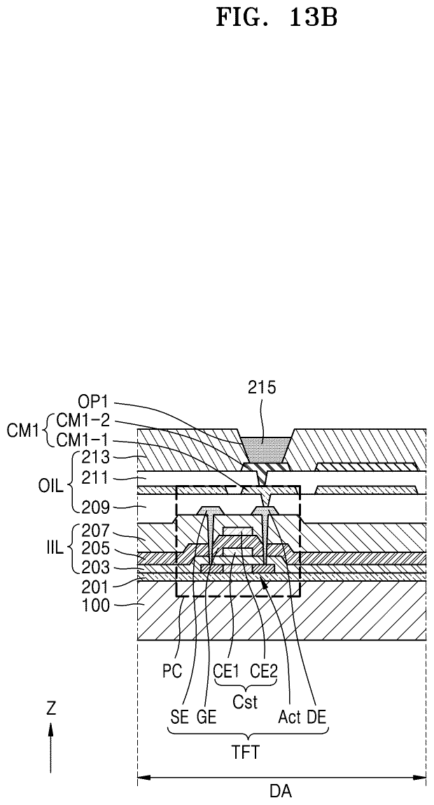

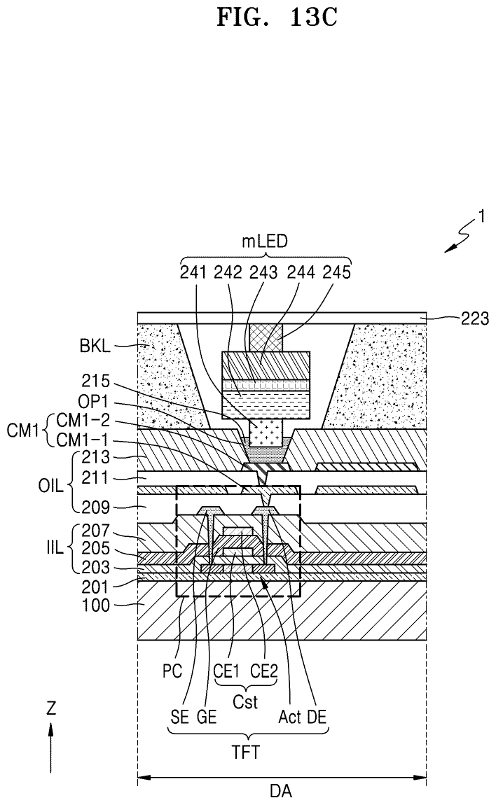

FIGS. 13A to 13C are schematic cross-sectional views of the display apparatus 1 according to an embodiment.

Referring to FIGS. 13A to 13C, the method of manufacturing the display apparatus 1 is described.

In FIGS. 13A to 13C, the same reference numerals as those of FIGS. 7 to 12 denote the same members, and thus, repeated descriptions thereof are omitted.

First, referring to FIG. 13A, the method of manufacturing the display apparatus 1 may include disposing the pixel driving circuit portion PC on the substrate 100, disposing the organic insulating layer OIL on the pixel driving circuit portion PC, and etching the organic insulating layer OIL to form the first opening OP1. The etching of the organic insulating layer OIL to form the first opening OP1 may include dry-etching the organic insulating layer OIL using an etching gas.

Referring to FIG. 13B, the method of manufacturing the display apparatus 1 may include disposing the first conductive organic film 215 in the first opening OP1. The first conductive organic film 215 may include a carbon black material. The first conductive organic film 215 may be accommodated in the first opening OP1 and be in contact with the first connection electrode CM1.

Referring to FIG. 13C, the method of manufacturing the display apparatus 1 may include disposing the inorganic light-emitting diode mLED on the organic insulating layer OIL and disposing the opposite electrode 223 on the inorganic light-emitting diode mLED.

The disposing of the inorganic light-emitting diode mLED may include accommodating at least a portion of the first electrode 241 in the first conductive organic film 215. The accommodating of at least a portion of the first electrode 241 in the first conductive organic film 215 may include pressing the first electrode 241 to the first conductive organic film 215 and heating the first conductive organic film 215.

Because the opposite electrode 223 is disposed on the inorganic light-emitting diode mLED, the second electrode 245 of the inorganic light-emitting diode mLED may be electrically connected to the opposite electrode 223. In this case, the opposite electrode 223 may be supported by the bank layer BKL.

The method of manufacturing the display apparatus 1 may include disposing the encapsulation layer 300 (see FIG. 7) on the opposite electrode 223 and disposing the filter panel 400 (see FIG. 7) over the encapsulation layer 300 (see FIG. 7), which are described with reference to FIGS. 7 and 9. Accordingly, detailed descriptions thereof are omitted.

In addition, although description is made with respect to the display area DA of the display apparatus 1 with reference to FIGS. 13A to 13C, the above-described process described with reference to FIGS. 11A to 11H may be also performed on the non-display area NDA of the display apparatus 1. That is, finally, in the non-display area NDA, the conductive organic film layer 221 for blocking light may be disposed on the organic insulating layer OIL.

The display apparatus 1 according to the embodiments may be used in various electronic apparatuses capable of displaying images. Here, the electronic apparatuses denote apparatuses that use electricity and may display preset images.

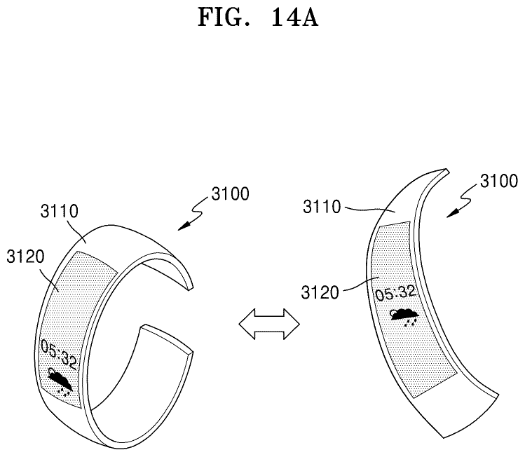

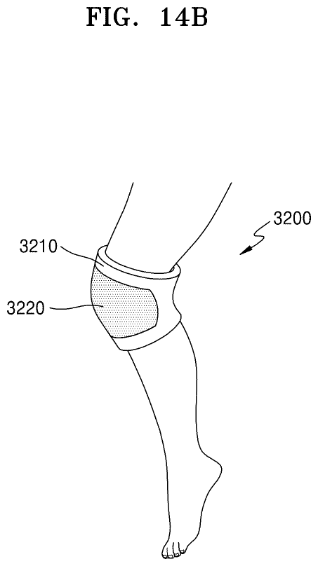

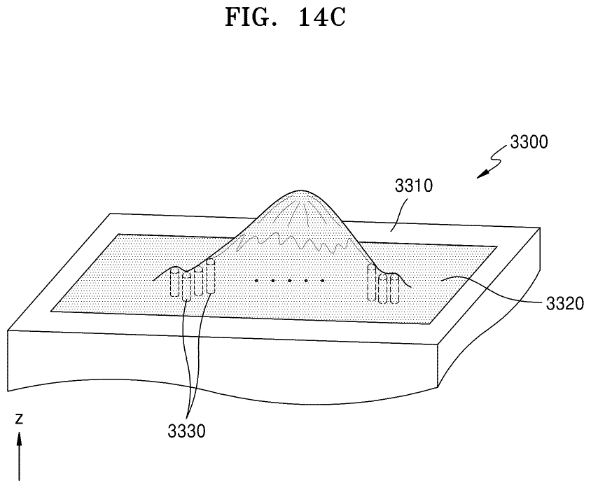

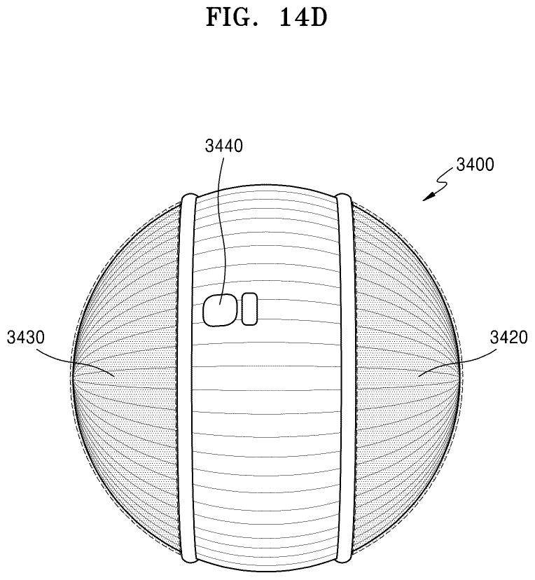

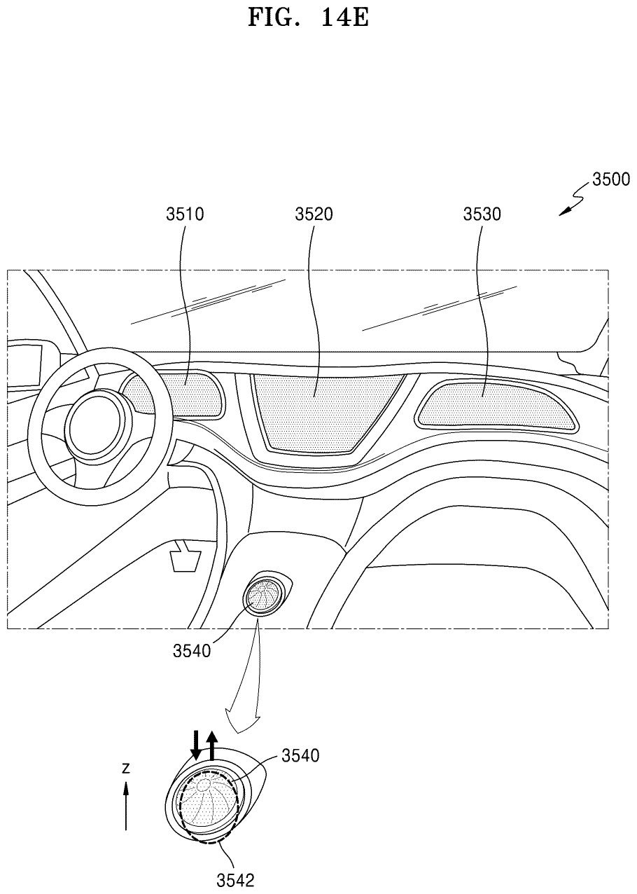

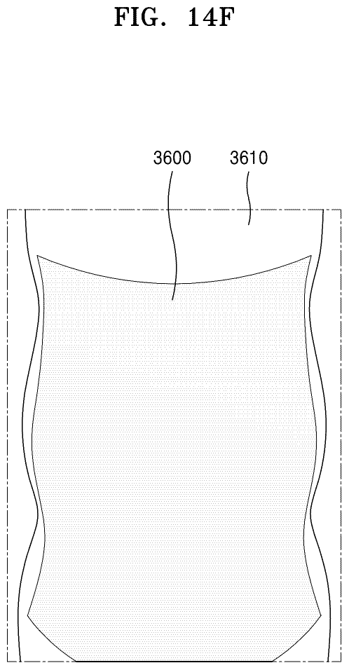

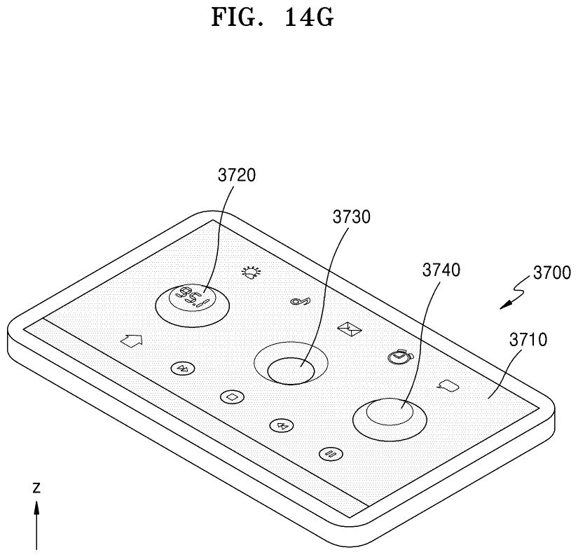

FIGS. 14A to 14G are schematic perspective views of embodiments of an electronic apparatus including the display apparatus according to an embodiment, respectively.

Referring to FIG. 14A, the display apparatus according to an embodiment may be utilized in a wearable electronic apparatus 3100 that may be worn on a portion of a user's body. The wearable electronic apparatus 3100 may include a body portion 3110 and a display 3120 provided to the body portion 3110. The display apparatus according to embodiments may be used as the display 3120 of the wearable electronic apparatus 3100. As shown in FIG. 14A, the wearable electronic apparatus 3100 may be transformed. In an embodiment, the wearable electronic apparatus 3100 may be used as a smartwatch or a smartphone depending on a user's selection.

FIG. 14B shows a medical electronic apparatus 3200. In an embodiment, the medical electronic apparatus 3200 may include a body portion 3210 and an emission portion 3220. The display apparatus according to embodiments may be used as the emission portion 3220 of the medical electronic apparatus 3200. The emission portion 3220 may be configured to emit light in a preset wavelength band (e.g., an infrared ray, a visible ray, and the like) to a patient's body. In an embodiment, the body portion 3210 may include a stretchable fiber material and may have a structure that may be worn on the body of the user who uses the emission portion.

FIG. 14C shows an educational electronic apparatus 3300. In an embodiment, the educational electronic apparatus 3300 may include a display 3320 provided inside a frame 3310. The display 3320 may use the display apparatus according to embodiments. Images such as sea with waves, a mountain covered with snow, or a volcano with flowing lava may be provided through the display 3320, and in this case, the display 3320 may extend in the height direction (e.g., a z direction) to reflect the height of waves, mountains, or volcanoes. In an embodiment, because a portion of the display 3320 may show the movements of lava three dimensionally by sequentially changing its height in a direction in which the lava flows. The educational electronic apparatus 3300 may include a plurality of pins 3330 (or stroke portions) disposed on the backside of the display 3320 such that the display 3320 extends in a height direction. As the pins 3330 move in the third direction (e.g., z direction or −z direction), the image displayed on the display 3320 may be implemented to have a three-dimensional height. Although FIG. 14C describes the educational electronic apparatus 3300, the purpose of the electronic apparatus is not limited as long as the electronic apparatus provides preset image information.

Although the electronic apparatuses shown in FIGS. 14A to 14C are described as electronic apparatuses whose shapes are variable, the embodiment is not limited thereto. As in embodiments described below, the display apparatus according to embodiments may be used in an electronic apparatus in which a portion (e.g., a screen) capable of displaying images is fixed.

FIG. 14D shows a robot 3400 as an electronic apparatus according to an embodiment. The robot 3400 may move or recognize an object by using a camera portion 3440 and display preset images to a user through displays 3420 and 3430. In an embodiment, because the display apparatuses according to an embodiment may be stretched in various directions as described above, the display apparatuses may be assembled to a body frame having a hemispherical shape, and thus, the robot 3400 may include the displays 3420 and 3430 having a hemispherical shape.

FIG. 14E shows a vehicle display apparatus 3500 as another electronic apparatus according to an embodiment. The vehicle display apparatus 3500 may include a cluster 3510, a center information display (“CID”) 3520, and/or a passenger display. Because the display apparatus according to an embodiment may be stretched in various directions, the display apparatus may be used as the cluster 3510, the CID 3520, and/or a co-driver display regardless of the shape of an internal frame of the vehicle.

Although it is shown in FIG. 14E that the cluster 3510, the CID 3520, and/or the co-driver display are separated from each other, the embodiment is not limited thereto. In another embodiment, two or more of the cluster 3510, the CID 3520, and/or the co-driver display may be integrally connected.

In an embodiment, the vehicle display apparatus 3500 may include a button 3540 that may display preset images. Referring to an enlarged view of FIG. 14E, the button 3540 having a hemispherical shape may include an object 3542 that provides the feeling of using the button while moving in the z direction or −z direction, and a display apparatus disposed on the object 3542. In an embodiment, in the case where the object 3542 has a surface rounded three-dimensionally, the display apparatus may also have a surface rounded three-dimensionally.

FIG. 14F shows that the electronic apparatus according to an embodiment is an electronic apparatus 3600 for advertising or exhibition. In an embodiment, the electronic apparatus 3600 for advertising or exhibition may be installed at a structure 3610 such as a wall or pillar. In the case where the structure 3610 includes an uneven surface as shown in FIG. 14F, the electronic apparatus 3600 for advertising or exhibition may be also disposed along the uneven surface of the structure 3610. In an embodiment, the electronic apparatus 3600 for advertising or exhibition may be installed at the structure 3610 using a heat shrink film and the like.

FIG. 14G shows that the electronic apparatus according to an embodiment is a controller 3700. The controller 3700 may include an image type button. As an example, the controller 3700 may include first to third bottom regions 3720, 3730, and 3740 in which a partial region of a display 3710 protrudes in a z direction or −z direction (or collapses in the z direction). In an embodiment, the first and third button regions 3720 and 3740 may protrude in the z direction, and the second button region 3730 may protrude in the −z direction (or collapse in the z direction).

According to an embodiment, the display apparatus in which a damage due to concentration of stress may be effectively prevented and which is configured to stretch in various directions may be provided.

According to an embodiment, fine patterning of the conductive organic film electrically connected to the pixel driving circuit portion may be performed, and the inorganic light-emitting diode may be connected to the conductive organic film even at low temperature and low pressure.

However, this effect is an example, and the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a pixel driving circuit portion disposed on the substrate;
an organic insulating layer disposed on the pixel driving circuit portion and defining a first opening therein;
a first conductive organic film accommodated in the first opening to be electrically connected to the pixel driving circuit portion; and
an inorganic light-emitting diode disposed on the organic insulating layer and including a first electrode,
wherein at least a portion of the first electrode is accommodated in the first conductive organic film.

2. The display apparatus of claim 1, wherein an upper surface of the first conductive organic film is recessed from a top surface of the organic insulating layer.

3. The display apparatus of claim 2, wherein a thickness of the first electrode is greater than a height difference between the upper surface of the first conductive organic film and the top surface of the organic insulating layer.

4. The display apparatus of claim 1, wherein the first conductive organic film includes a carbon black material.

5. The display apparatus of claim 1, further comprising a first connection electrode disposed between the pixel driving circuit portion and the first conductive organic film and electrically connecting the pixel driving circuit portion to the first conductive organic film.

6. The display apparatus of claim 5, wherein the first connection electrode includes at least one of indium tin oxide (ITO), indium zinc oxide (IZO), and molybdenum (Mo).

7. The display apparatus of claim 1, further comprising a second conductive organic film apart from the first conductive organic film,
wherein the organic insulating layer further defines a second opening which is apart from the first opening and accommodates the second conductive organic film, and
the inorganic light-emitting diode further includes a second electrode which is apart from the first electrode and has at least a portion accommodated in the second conductive organic film.

8. The display apparatus of claim 7, wherein an upper surface of the second conductive organic film is recessed from the top surface of the organic insulating layer.

9. The display apparatus of claim 8, wherein a thickness of the second electrode is greater than a height difference between the upper surface of the second conductive organic film and the top surface of the organic insulating layer.

10. The display apparatus of claim 7, wherein the second conductive organic film includes a carbon black material.

11. The display apparatus of claim 7, further comprising a second connection electrode disposed between the pixel driving circuit portion and the second conductive organic film and connected to the second conductive organic film.

12. The display apparatus of claim 11, wherein the second connection electrode includes at least one of indium tin oxide (ITO), indium zinc oxide (IZO), and molybdenum (Mo).

13. The display apparatus of claim 1, further comprising an opposite electrode disposed on the inorganic light-emitting diode,
wherein the inorganic light-emitting diode further includes a second electrode which is apart from the first electrode and is electrically connected to the opposite electrode.

14. The display apparatus of claim 1, further comprising a conductive organic film layer disposed on the organic insulating layer to cover the organic insulating layer in a non-display area.

15. A method of manufacturing a display apparatus, the method comprising:
disposing a pixel driving circuit portion on a substrate;
disposing an organic insulating layer on the pixel driving circuit portion;
etching the organic insulating layer to form a first opening;
disposing a first conductive organic film in the first opening to be electrically connected to the pixel driving circuit portion; and
disposing an inorganic light-emitting diode on the organic insulating layer,
wherein the disposing of the inorganic light-emitting diode includes accommodating at least a portion of a first electrode of the inorganic light-emitting diode in the first conductive organic film.

16. The method of claim 15, wherein the etching of the organic insulating layer to form the first opening includes dry-etching the organic insulating layer using an etching gas.

17. The method of claim 15, wherein the disposing of the first conductive organic film includes:
disposing a conductive organic film material on the organic insulating layer;
soft-baking the conductive organic film material; and
developing the conductive organic film material.

18. The method of claim 15, wherein the accommodating of at least a portion of the first electrode in the first conductive organic film includes:
pressing the first electrode to the first conductive organic film; and
heating the first conductive organic film.

19. The method of claim 18, wherein the heating of the first conductive organic film includes heating the first conductive organic film to about 120 degrees in Celsius (C) to about 140° C.

20. The method of claim 15, wherein the first conductive organic film includes a carbon black material.

21. The method of claim 15, further comprising:
etching the organic insulating layer to form a second opening apart from the first opening; and
disposing a second conductive organic film in the second opening,
wherein the disposing of the inorganic light-emitting diode further includes accommodating at least a portion of a second electrode of the inorganic light-emitting diode in the second conductive organic film, and the second electrode is apart from the first electrode.

22. The method of claim 21, wherein the etching of the organic insulating layer to form the first opening, and the etching of the organic insulating layer to form the second opening are performed simultaneously.

23. The method of claim 21, wherein the disposing of the first conductive organic film in the first opening, and the disposing of the second conductive organic film in the second opening are performed simultaneously.

24. The method of claim 21, wherein the accommodating of the at least a portion of the first electrode in the first conductive organic film, and the accommodating of the at least a portion of the second electrode in the second conductive organic film are performed simultaneously.

25. The method of claim 15, further comprising disposing an opposite electrode on the inorganic light-emitting diode,
wherein the disposing of the inorganic light-emitting diode further includes electrically connecting a second electrode of the inorganic light-emitting diode to the opposite electrode, and the second electrode is apart from the first electrode.
